(19) United States
(12) Patent Application Publication
(10) Pub. No.: US 2011/0220886 A1
(43) Pub. Date: Sep. 15, 2011

(54) ORGANIC ELECTROLUMINESCENCE MATERIAL COMPOSITION, THIN FILM FORMATION METHOD, AND ORGANIC ELECTROLUMINESCENCE ELEMENT

(75) Inventors: Motohiro Takeshima, Chiba (JP); Atau Ioku, Chiba (JP); Tetsuya Inoue, Chiba (JP); Yoshiaki Obana, Tokyo (JP); Yukio Miyaki, Tokyo (JP); Keisuke Matsuo, Tokyo (JP); Yasunori Kijima, Tokyo (JP)

(73) Assignees: IDEMITSU KOSAN CO., LTD., Tokyo (JP); SONY CORPORATION, Tokyo (JP)

(21) Appl. No.: 13/119,591

(22) PCT Filed: Sep. 16, 2009
(86) PCT No.: PCT/JP2009/004630

§ 371 Date: May 23, 2011

(30) Foreign Application Priority Data
Sep. 19, 2008 (JP) 2008-241348

(51) Int. Cl. H01L 51/54; C09K 11/06; B05D 5/06; B05D 5/12; B05D 3/00

(52) U.S. Cl. 257/40; 252/301.16; 427/66; 257/E51.024

(57) ABSTRACT

An organic electroluminescence material composition including a solvent represented by the following formula (1) and an anthracene derivative:
wherein ring A is an aliphatic ring or an aromatic ring having 4 to 8 carbon atoms; R¹ is a substituent on the ring A; and
R² and R³ are substituents connected to adjacent carbon atoms on the ring A.

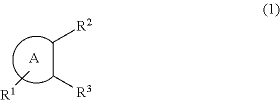

### TECHNICAL FIELD

The invention relates to a coating liquid (composition) containing a material for an organic electroluminescence device. For example, the invention relates to a solution containing an organic electroluminescence material which is used when forming an organic thin film constituting an organic electroluminescence device by a coating method.

### BACKGROUND ART

An organic electroluminescence (EL) device is a self-emission device utilizing the principle that a fluorescent compound emits light by the recombination energy of holes injected from an anode and electrons injected from a cathode when an electric field is impressed.

As the material constituting such an organic EL device, a low-molecular organic EL material is known.

As the low-molecular organic EL material, emitting materials such as a chelate complex such as a tris(8-quinolinol)aluminum complex, a coumalin complex, a tetraphenylbutadiene derivative, a bisstyryl arylene derivative and an oxadiazole derivative are known. Since it is reported that they can emit light in the visible range from blue to red, development of a color display using it is expected.

For forming an organic EL material into a film, deposition has conventionally been used. Deposition has problems of complicated production processes, poor raw material utilization efficiency or the like. Therefore, in recent years, film formation has come to be conducted by a coating method.

For example, in Patent Document 1, a thin film of an organic EL material is formed by using an organic EL material dissolved in a solvent. This coating method has advantages that a thin film of an organic EL material can be formed easily at a low cost and color coding can be conducted easily.

However, although a coating method is generally used for forming a high-molecular EL material into a film, a high-molecular organic EL material is synthesized through a complicated process, and purification to a high purity is also difficult. For this reason, a high-molecular organic EL material improved in luminous efficiency, life, color purity or the like has not been known yet. In particular, a blue-emitting high-molecular organic EL material has poor performance as compared with a blue-emitting low-molecular organic EL material.

Under such circumstances, forming into a film a low-molecular organic EL material by a coating method has been studied. In forming a thin film of an organic EL material by a coating method, it is required to dissolve an organic EL material in a solvent.

In the case of a high-molecular organic EL material, a coating composition obtained by dissolving it in a solvent such as toluene, xylene and tetraline is generally known (see Patent Document 2, for example).

However, a low-molecular organic EL material has a low solubility in such a solvent, and hence, it is impossible to prepare a coating liquid at a high concentration. Therefore, a coating liquid obtained by dissolving a low-molecular organic EL material has a problem such as solubility and viscosity.

When an organic EL material is formed into a film by a coating method such as the ink printing method and the nozzle jet method, it is disclosed that cyclohexylbenzene, 3-isopropylbiphenyl, 2,3-dihydrobenzofurane or the like is used for a high-molecular organic EL material as a solvent (see Patent Documents 3 and 4). However, since these solvents have high water absorptivity since the polarity thereof is relatively high, the amount of water in a coating liquid prepared may be increased with the passage of time. If water remains in a thin film after the film formation, the remaining water may significantly deteriorate the performance of an organic EL device. Therefore, it is preferred that the amount of water be small not only in a film formed by a coating film but also in a coating liquid used therefor. In a coating liquid using the above-mentioned solvent, the amount of water in a coating liquid may tend to be increased easily, and as a result, the device performance may be readily deteriorated.

Under such circumstances, the inventors of the invention have found that even a low-molecular material can be formed into a film by a coating method (see Patent Document 5). However, it is preferable to further increase the concentration of a low-molecular material in a coating liquid. Further, since the storage stability of a coating composition is low, the performance of a device fabricated using it may be lowered. Therefore, further improvement is required.

### PRIOR ART DOCUMENTS

### Patent Documents

Patent Document 1: JP-A-2003-229256

Patent Document 2: WO2000/059267

Patent Document 3: Japanese Patent No. 3896876

Patent Document 4: JP-A-2004-179144

Patent Document 5: JP-A-2006-190759

### SUMMARY OF THE INVENTION

As mentioned above, forming into a film a low-molecular organic EL material significantly improved in luminous efficiency, lifetime and color purity by a coating method has been desired in order to form a thin film easily at a low cost. However, an organic EL material composition improved in long-term storage stability has not been found yet so far. If an organic EL material composition improved in long-term storage stability can be found, stable production of an organic EL device becomes possible, and hence, full-scale practical use of an organic EL device can be expected.

The object of the invention is to provide an organic EL material composition capable of forming into a film an organic EL material by a coating method which can form a thin film easily at a low cost, and to provide an organic EL material composition improved in long-term storage stability at a desired concentration.

As a result of intensive studies, the inventors have found that a solvent which has a specific structure surprisingly dissolves an anthracene derivative, which is an organic EL material, at a high concentration. The inventors have also found that a composition obtained by combining the above-mentioned solvent and an anthracene derivative undergoes a significantly small change in physical properties when stored for a long period of time, and have found that the lifetime of a device fabricated by using this composition is hardly affected by the period of the storage of the composition. The invention has been made based on this finding.

According to the invention, the following organic EL material composition or the like are provided.
1. An organic electroluminescence material composition comprising a solvent represented by the following formula (1) and an anthracene derivative:

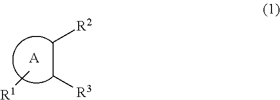

wherein ring A is an aliphatic ring or an aromatic ring having 4 to 8 carbon atoms;

R¹ is a substituent on the ring A, which may be present in plural on the ring A, and is independently a hydrogen atom, a substituted or unsubstituted alkyl group having 1 to 10 carbon atoms, a substituted or unsubstituted cycloalkyl group, a substituted or unsubstituted alkoxy group having 1 to 10 carbon atoms, a substituted or unsubstituted aryl group having 6 to 10 carbon atoms that form a ring (hereinafter referred to as “ring carbon atoms”), a substituted or unsubstituted aralkyl group having 7 to 11 carbon atoms, a substituted or unsubstituted aryloxy group having 6 to 10 atoms that form a ring (hereinafter referred to as “ring atoms”), a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group, or a nitro group;

R² and R³ are substituents connected to adjacent carbon atoms on the ring A, which are independently a substituted or unsubstituted alkyl group having 1 to 10 carbon atoms, a substituted or unsubstituted alkenyl group having 1 to 10 carbon atoms, a substituted or unsubstituted cycloalkyl group, a substituted or unsubstituted cycloalkenyl group, a substituted or unsubstituted alkoxy group having 1 to 10 carbon atoms, a substituted or unsubstituted aryl group having 6 to 10 ring carbon atoms, a substituted or unsubstituted aralkyl group having 7 to 11 carbon atoms, a substituted or unsubstituted aryloxy group having 6 to 10 ring atoms, a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group or a nitro group; and R² and R³ may be combined with each other to form a ring.
2. The organic electroluminescence material composition according to 1, wherein the ring A is a hydrocarbon ring having 6 carbon atoms.
3. The organic electroluminescence material composition according to 1 or 2, wherein the R² and R³ are combined with each other to form a ring, and the ring is a substituted or unsubstituted hydrocarbon ring having 4 to 10 carbon atoms or a substituted or unsubstituted heterocyclic ring having 2 to 10 carbon atoms.
4. The organic electroluminescence material composition according to one of 1 to 3, wherein the ring formed by R² and R³ are substituted or unsubstituted cyclopentane, substituted or unsubstituted cyclopentene, substituted or unsubstituted cyclopentadiene, substituted or unsubstituted benzene, substituted or unsubstituted cyclohexadiene, substituted or unsubstituted cyclohexane, substituted or unsubstituted cycloheptatriene, substituted or unsubstituted cycloheptadiene, substituted or unsubstituted cycloheptene or substituted or unsubstituted cycloheptane.
5. The organic electroluminescence material composition according to 1 or 2, wherein R¹ to R³ are independently a substituted or unsubstituted alkyl group having 1 to 10 carbon atoms.
6. The organic electroluminescence material composition according to one of 1 to 5, wherein the anthracene derivative has a molecular weight of 4000 or less.
7. The organic electroluminescence material composition according to 6, wherein the anthracene derivative is a compound represented by the following formula (3):

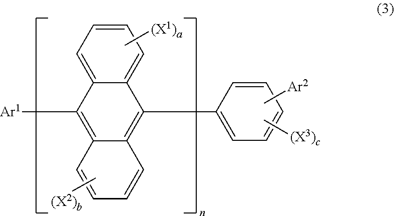

wherein Ar¹ is a substituted or unsubstituted fused aromatic group having 10 to 50 ring carbon atoms;

Ar² is a substituted or unsubstituted aromatic group having 6 to 50 ring carbon atoms;

X¹ to X³ are independently a substituted or unsubstituted aromatic group having 6 to 50 ring carbon atoms, a substituted or unsubstituted aromatic heterocyclic group having 5 to 50 ring atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a carboxy group, a halogen atom, a cyano group, a nitro group, or a hydroxyl group;

a, b and c are independently an integer of 0 to 4; and

n is an integer of 1 to 3, and when n is 2 or more, the groups in [ ] may be the same or different.
8. The electroluminescence material composition according to one of 1 to 7, which further comprises one or more dopants.
9. The electroluminescence material composition according to 8, wherein the dopant is a styrylamine derivative represented by the following formula (8):

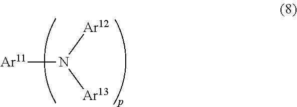

wherein Ar¹¹ is a residue corresponding to benzene, biphenyl, terphenyl, stilbene or distyrylarene; Ar¹² and Ar¹³, which each may be substituted, are independently a hydrogen atom or an aromatic group having 6 to 20 carbon atoms; p is an integer of 1 to 4; and at least one of Ar¹¹ to Ar¹³ is a styryl group or a group having a styryl group.
10. The organic electroluminescence material composition according to 8, wherein the dopant is an arylamine derivative represented by the formula (9):

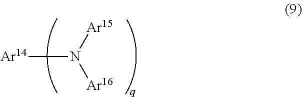

wherein Ar¹⁴ is a residue corresponding to a substituted or unsubstituted arene having 5 to 40 ring carbon atoms; Ar¹⁵ and Ar¹⁶ are independently a substituted or unsubstituted aryl group having 5 to 40 ring carbon atoms; and q is an integer of 1 to 4.
11. A method for forming a thin film comprising applying the organic electroluminescence material composition according to one of 1 to 10 on a base to form a film, and removing a solvent from the film.
12. An organic electroluminescence device comprising:

an anode and a cathode; and

one or more organic thin film layers comprising an emitting layer between the anode and the cathode;

at least one of the organic thin film layers being a thin film obtained by the method according to 11.

According to the invention, it is possible to provide an organic EL material composition improved in storage stability. As a result, if an organic EL device is fabricated by using the composition which is stored for a long time after the preparation thereof, a device having performance equivalent to that prepared by using the composition immediately after the preparation thereof can be produced. That is, since a change with the passage of time of the composition is significant small, stable production of an organic EL device becomes possible.

Furthermore, due to the organic EL material composition, a coating method capable of forming an organic thin film easily at a low cost can be used, whereby a highly uniform organic thin film can be formed stably. Therefore, the quality of an organic EL device can be stabilized.

### MODE FOR CARRYING OUT THE INVENTION

The organic EL material composition of the invention contains the solvent represented by the following formula (1) and an anthracene derivative.

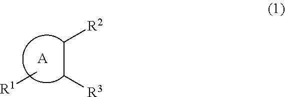

In the formula (1), the ring A is an aliphatic ring or an aromatic ring having 4 to 8 carbon atoms.

The ring A is preferably cyclopentane, cyclopentene, cyclopentadiene, benzene, cyclohexane, cyclohexene, cyclohexadiene, cycloheptane, cycloheptene and cycloheptadiene.

The ring A is more preferably a hydrocarbon ring having 6 carbon atoms. Specific examples thereof include benzene, cyclohexane, cyclohexene and cyclohexanediene.

R¹ is a substituent on the ring A, and R¹ may be present in plural on the ring A. R¹ is independently a hydrogen atom, a substituted or unsubstituted alkyl group having 1 to 10 carbon atoms, a substituted or unsubstituted cycloalkyl group, a substituted or unsubstituted alkoxy group having 1 to 10 carbon atoms, a substituted or unsubstituted aryl group having 6 to 10 ring carbon atoms, a substituted or unsubstituted aralkyl group having 7 to 11 carbon atoms, a substituted or unsubstituted aryloxy group 6 to 10 ring atoms, a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group or a nitro group.

As the alkyl group having 1 to 10 carbon atoms, a methyl group, an ethyl group, an n-propyl group, an iso-propyl group, an n-butyl group, an iso-butyl group, a sec-butyl group, a t-butyl group, an n-pentyl group, an n-hexyl group, an n-heptyl group, an n-octyl group, an n-nonyl group, an n-decyl group, or the like are preferable, for example.

As the cycloalkyl group, a cyclopropyl group, a cyclobutyl group, a cyclopentyl group, a cyclohexyl group, a cycloheptyl group, a cyclooctyl group, a cyclononyl group, a cyclodecyl group, or the like are preferable, for example.

As an alkoxy group having 1 to 10 carbon atoms, a methoxy group, an ethoxy group, a propoxy group, a butoxy group, a pentyloxy group, a hexyloxy group, a heptyloxy group, an octyloxy group, a nonyloxy group, a decyloxy group, or the like are preferable, for example.

As the substituted or unsubstituted aryl group having 6 to 10 ring carbon atoms, a phenyl group, a methylphenyl group, a dimethylphenyl group, an ethylphenyl group, a trimethylphenyl group, a propylphenyl group, a tetramethylphenyl group, a diethylphenyl group, a butylphenyl group, an indenyl group, an indanyl group, a naphthyl group, or the like are preferable, for example.

As the aralkyl group having 7 to 11 carbon atoms, a benzyl group, a phenylethyl group, a phenylpropyl group, a phenylbutyl group, an indenylmethyl group, an indanylmethyl group, a naphthylmethyl group, or the like are preferable, for example.

As the substituted or unsubstituted aryloxy group having 6 to 10 ring atoms, a phenoxy group, a benzyloxy group, a methylphenoxy group, a dimethylphenoxy group, an ethylphenoxy group, a trimethylphenoxy group, a propylphenoxy group, a tetramethylphenoxy group, a diethylphenoxy group, a butylphenoxy group, an oxynaphthyl group, an oxyindanyl group, an oxyindenyl group, or the like are preferable, for example.

As the substituted or unsubstituted arylthio group having 6 to 10 ring atoms, a thiophenyl group, a thiobenzyl group, a thiomethylphenyl group, a thiodimethylphenyl group, a thioethylphenyl group, a thiotrimethylphenyl group, a thiopropylphenyl group, a thiotetramethylphenyl group, a thiodiethylphenyl group, a thiobutylphenyl group, a thionaphthyl group, a thioindenyl group, a thioindanyl group, or the like are preferable, for example.

As the alkoxycarbonyl group having 1 to 10 carbon atoms, a methoxycarbonyl group, an ethoxycarbonyl group, a propoxycarbonyl group, a butoxycarbonyl group, a pentyloxycarbonyl group, a hexyloxycarbonyl group, a heptyloxycarbonyl group, an octyloxycarbonyl group, a nonyloxycarbonyl group, or the like are preferable, for example.

As the substituted or unsubstituted silyl group, a trimethylsilyl group, a trimethoxysilyl group, a triethylsilyl group, a triethoxysilyl group, a chlorodimethylsilyl group, a triisopropylsilyl group, a triisopropoxysilyl group, or the like are preferable, for example.

If the above-mentioned group has a substituent, as the substituent, a substituted or unsubstituted alkyl group having 1 to 10 carbon atoms, a substituted or unsubstituted cycloalkyl group, a substituted or unsubstituted alkoxy group having 1 to 10 carbon atoms, a substituted or unsubstituted aralkyl group having 6 to 10 carbon atoms, a substituted or unsubstituted aryloxy group having 6 to 10 ring atoms, a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group, a nitro group, or a hydroxyl group, as mentioned above, can be given.

R² and R³ are substituents connected to adjacent carbon atoms on the ring A, which are independently a substituted or unsubstituted alkyl group having 1 to 10 carbon atoms, a substituted or unsubstituted alkenyl group having 1 to 10 carbon atoms, a substituted or unsubstituted cycloalkyl group, a substituted or unsubstituted cycloalkenyl group, a substituted or unsubstituted alkoxy group having 1 to 10 carbon atoms, a substituted or unsubstituted aryl group having 6 to 10 ring carbon atoms, a substituted or unsubstituted aralkyl group having 6 to 10 carbon atoms, a substituted or unsubstituted aryloxy group having 6 to 10 ring atoms, a substituted or unsubstituted arylthio group having 6 to 10 ring atoms, a substituted or unsubstitued alkoxycarbonyl group having 1 to 10 carbon atoms, a substituted or unsubstituted silyl group, a carboxy group, a halogen atom, a cyano group, or a nitro group.

The specific examples of each substituent are the same as those for R¹ mentioned above.

As the substituted or unsubstituted alkenyl group having 1 to 10 carbon atoms, an ethenyl group, a propenyl group, a butenyl group, a pentenyl group, a pentadienyl group, a hexenyl group, a hexadienyl group, a heptenyl group, an octenyl group, an octadienyl group, a 2-ethylhexenyl group, a decenyl group, or the like are preferable.

As the cycloalkenyl group, a cyclobutenyl group, a cyclopentenyl group, a cyclopentadienyl group, a cyclohexenyl group, a cyclohexadienyl group, a cycloheptenyl group, a cyclooctenyl group, a cyclooctadienyl group, or the like are preferable.

When the above-mentioned groups have a substituent, as the examples of the substituent, the same examples as those for R¹ mentioned above can be given.

R² and R³ may be combined with each other to form a ring. As the ring, a substituted or unsubstituted hydrocarbon ring having 4 to 10 carbon atoms or a substituted or unsubstituted heterocyclic ring having 2 to 10 carbon atoms are preferable.

Specific examples thereof include a substituted or unsubstituted cycloalkane having 4 to 10 carbon atoms, a substituted or unsubstituted cycloalkene having 4 to 10 carbon atoms, a substituted or unsubstituted cycloxyalkane having 3 to 10 carbon atoms, a substituted or unsubstituted cycloxyalkene having 3 to 10 carbon atoms, a substituted or unsubstituted cyclothioalkane having 3 to 10 carbon atoms, a substituted or unsubstituted cyclothioalkene having 3 to 10 carbon atoms, a substituted or unsubstituted cycloazalkane having 3 to 10 carbon atoms, a substituted or unsubstituted cycloazalkene having 3 to 10 carbon atoms, a substituted or unsubstituted aromatic ring having 6 to 10 ring atoms, a substituted or unsubstituted oxygen-containing aromatic ring having 5 to 10 ring atoms, a substituted or unsubstituted sulfur-containing aromatic ring having 5 to 10 ring atoms and a nitrogen-containing aromatic ring having 5 to 10 ring atoms.

Of these, substituted or unsubstituted cyclopentane, substituted or unsubstituted cyclopentene, substituted or unsubstituted cyclopentadiene, substituted or unsubstituted benzene, substituted or unsubstituted cyclohexadiene, a substituted or unsubstituted cyclohexane, substituted or unsubstituted cycloheptatriene, substituted or unsubstituted cycloheptadiene, substituted or unsubstituted cycloheptene, and substituted or unsubstituted cycloheptane are preferable.

Specific examples of the solvent represented by the formula (1) include indene, indane, 2-methylanisole, 3a,4,7,7a-tetra-hydroindene, 2-ethyltoluene, 1,2-methylenedioxybenzene, 2,3-dihydrobenzofuran, 1,2,4-trimethylbenzene, 1,2,3-trimethylbenzene, 2-ethylanisole, 2,5-dimethylanisole, 2,3-dihydro-2-methylbenzofuran, 1,2,3,5-tetramethylbenzene, 1,2-dihydronaphthalene, tricyclo[6.2.1.0(2,7)]undeca-4-ene, 4-tert-butyl-o-xylene, 1,4-dihydronaphthalene, 2,5-dimethoxy toluene, 1-acetyl-1,2,3,4-tetra-hydroquinoline, N-methylindole, 2-isopropyl naphthalene, dimethyl phthalate, 2, 6-dimethylanisole, 2-ethylphenyl acetate, o-tolyl acetate, 3,4-dihydro-1H-2-benzopyrane, 6-methoxy-1,2,3,4-tetrahydronaphthalene, 5,6,7,8-tetrahydroisoquinoline, and tetrahydrodicyclopentadiene.

By using a solvent having a ring structure represented by the formula (1) as the main skeleton, in which a substituent is introduced into the first and second positions thereof or into two adjacent elements on the ring skeleton, it is possible to enhance the solubility of an anthracene derivative. Therefore, an anthracene derivative having a desired concentration can be obtained.

In addition, by using such a solvent, a change with time of physical properties and film-forming properties of an organic EL material composition is significantly small, whereby uniformity of a thin film obtained from this composition is enhanced.

Due to the ring structure in the basic skeleton, the above-mentioned solvent is improved in lipophilicity. Both an aliphatic ring or an aromatic ring are improved in lipophilicity and hydrophobicity, and an aromatic 6-membered ring compound, in particular, shows further high lipophilicity and hydrophobicity. Therefore, it is expected that the water content and/or the oxygen content of these solvents are kept at a low level.

The “pot life” can be given as one of the criteria for evaluating an organic EL material composition. The “pot life” is a criterion to evaluate usable days of a composition by counting the days passed until precipitates are generated in a composition which was a homogeneous solution immediately after the preparation. In respect of long-term storage stability, a longer pot life is better. The pot life is preferably two weeks or more, more preferably one month or more.

The composition of the invention has a long pot life, and a change with the passage of time of the physical properties thereof is significantly small.

Regarding the solvent, the above-mentioned solvents may be used singly or in a mixture of two or more. The solvent may be used in a mixture with a solvent other than those mentioned above. If a mixed solution is used, the content of the solvent represented by the formula (1) is preferably 20% (weight) or more, further preferably 50% or more, with 75% or more being particularly preferable. In order to improve the solubility of an anthracene derivative, it is preferred that the ratio of the solvent represented by the formula (1) be high.

No particular restrictions are imposed on an anthracene derivative used in the invention as long as it can be used as an organic EL device material. In view of the object of the invention, the molecular weight of an anthracene derivative is preferably 4000 or less. Taking into the luminous efficiency of an organic EL device fabricated using an anthracene derivative, it is preferred that an anthracene derivative have three or more benzene ring structures in addition to one anthracene skeleton. For example, 9,10-diphenylanthracene, which has two benzene rings in addition to the anthracene skeleton, the luminous efficiency is slightly low. Therefore, diphenylanthracene may be excluded from anthracene derivatives to be used in the invention. As for the benzene ring structure, naphthalene is defined as one which has two benzene ring structures, for examples.

As preferable anthracene derivatives, compounds represented by the following formulas (2) to (7) can be given.

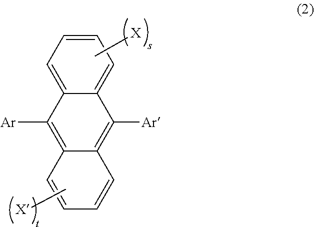

wherein Ar and Ar′ are independently an aryl group having 6 to 50 ring carbon atoms which each may have a substituent or a heteroaryl group having 5 to 50 ring atoms which each may have a substituent, and Ar and Ar′ are not the same;

X and X′ are substituents which may be the same or different;

the total number of the aryl rings of Ar, Ar′, X and X′ is preferably three or more;

s and t are independently an integer of 0 to 4; and

when s or t is 2 or more, Xs and X′s may be the same or different.

Asymmetrical anthracene represented by the following formula (3):

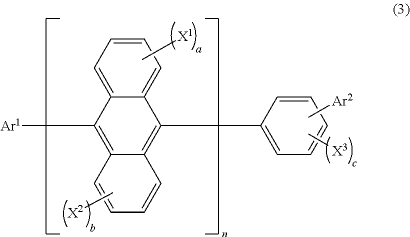

wherein Ar¹ is a substituted or unsubstituted fused aromatic group having 10 to 50 ring carbon atoms,

Ar² is a substituted or unsubstituted aromatic group having 6 to 50 ring carbon atoms,

X¹ to X³ are independently a substituted or unsubstituted aromatic group having 6 to 50 ring carbon atoms, a substituted or unsubstituted aromatic heterocyclic group having 5 to 50 ring atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a carboxy group, a halogen atom, a cyano group, a nitro group or a hydroxyl group;

a, b and c are each an integer of 0 to 4; and

n is an integer of 1 to 3, and when n is two or more, the groups in [ ] may be the same or different.

Asymmetrical monoanthracene derivatives represented by the following formula (4):

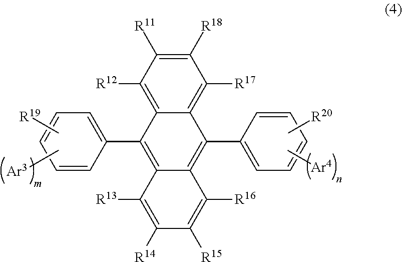

wherein Ar³ and Ar⁴ are independently a substituted or unsubstituted aromatic ring group having 6 to 50 ring carbon atoms, and m and n are each an integer of 1 to 4, provided that in the case where m=n=1 and Ar³ and Ar⁴ are symmetrically bonded to the benzene rings, Ar³ and Ar⁴ are not the same, and in the case where m or n is an integer of 2 to 4, m is different from n.

R¹¹ to R²⁰ are independently a hydrogen atom, a substituted or unsubstituted aromatic ring group having 6 to 50 ring carbon atoms, a substituted or unsubstituted aromatic heterocyclic group having 5 to 50 ring atoms, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a substituted or unsubstituted silyl group, a carboxy group, a halogen atom, a cyano group, a nitro group or a hydroxyl group.

Asymmetrical anthracene derivatives represented by the following formula (5):

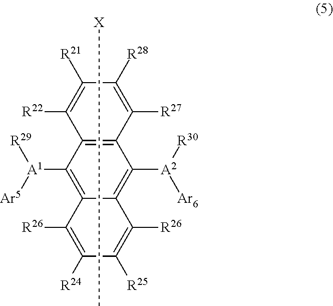

wherein A¹ and A² independently a substituted or unsubstituted fused aromatic ring group having 10 to 20 ring carbon atoms,

Ar⁵ and Ar⁶ are independently a hydrogen atom or a substituted or unsubstituted aromatic ring group with 6 to 50 ring carbon atoms,

R²¹ to R³⁰ are independently a hydrogen atom or a substituted or unsubstituted aromatic ring group having 6 to 50 ring carbon atoms, a substituted or unsubstituted aromatic hetrocyclic group having 5 to 50 ring atoms, a substituted or unsubstituted alkyl group having 1 to 50 carbon atoms, a substituted or unsubstituted cycloalkyl group, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a substituted or unsubstituted silyl group, a carboxy group, a halogen atom, a cyano group, a nitro group or a hydroxyl group, and

Ar⁵, Ar⁶, R²⁹ and R³⁰ each may be plural, and adjacent groups thereof may form a saturated or unsaturated ring structure,

provided that, in the formula (5), groups do not symmetrically bond to the 9^{th} and 10^{th} positions of the central anthracene with respect to X-Y axis.

Anthracene derivatives represented by the following formula (6):

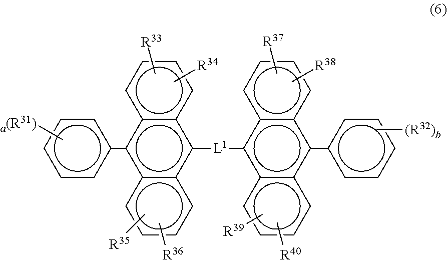

wherein R³¹ to R⁴⁰ are independently a hydrogen atom, an alkyl group, a cycloalkyl group, an aryl group which may be substituted, an alkoxy group, an aryloxy group, an alkylamino group, an alkenyl group, an arylamino group or a heterocyclic group which may be substituted; a and b are each an integer of 1 to 5; when they are 2 or more, R³¹s or R³²s may be the same or different, or R³¹s or R³²s may be bonded to each other to form a ring; R³³ and R³⁴, R³⁵ and R³⁶, R³⁷ and R³⁸, or R³⁹ and R⁴⁰ may be bonded to each other to form a ring, L¹ is a single bond, —O—, —S—, —N(R)— (R is an alkyl group or a substituted or unsubstituted aryl group), an alkylene group or an arylene group.

Anthracene derivatives represented by the following formula (7):

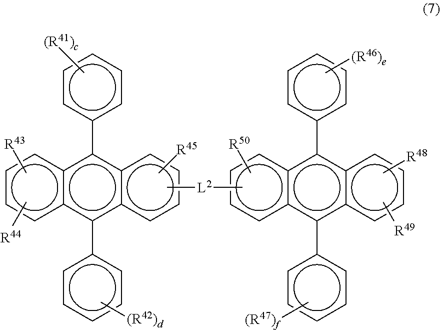

wherein R⁴¹ to R⁵⁰ independently a hydrogen atom, an alkyl group, a cycloalkyl group, an aryl group, an alkoxy group, an aryloxy group, an alkylamino group, an arylamino group or a heterocyclic group which may be substituted; c, d, e and f are each an integer of 1 to 5; when they are 2 or more, R⁴¹s, R⁴²s, R⁴⁶s or R⁴⁷s may be the same or different, R⁴¹s, R⁴²s, R⁴⁶s or R⁴⁷s may be bonded to each other to form a ring, or R⁴³ and R⁴⁴, or R⁴⁸ and R⁴⁹ may be bonded to each other to form a ring. L² is a single bond, —O—, —S—, —N(R)— (R is an alkyl group or a substituted or unsubstituted aryl group), an alkylene group or an arylene group.

The above-mentioned anthracene derivatives are highly effective as a host of an emitting layer of an organic EL device. Therefore, an organic EL thin film formed by a coating method using a solution containing an organic EL material of the invention exhibits high performance in respect of luminous efficiency, life time, color purity or the like.

Of the above-mentioned anthracene derivatives, those represented by the formula (3) are preferable.

It is preferred that an anthracene derivative be used as a host material in an emitting layer. Specific examples thereof are given below.

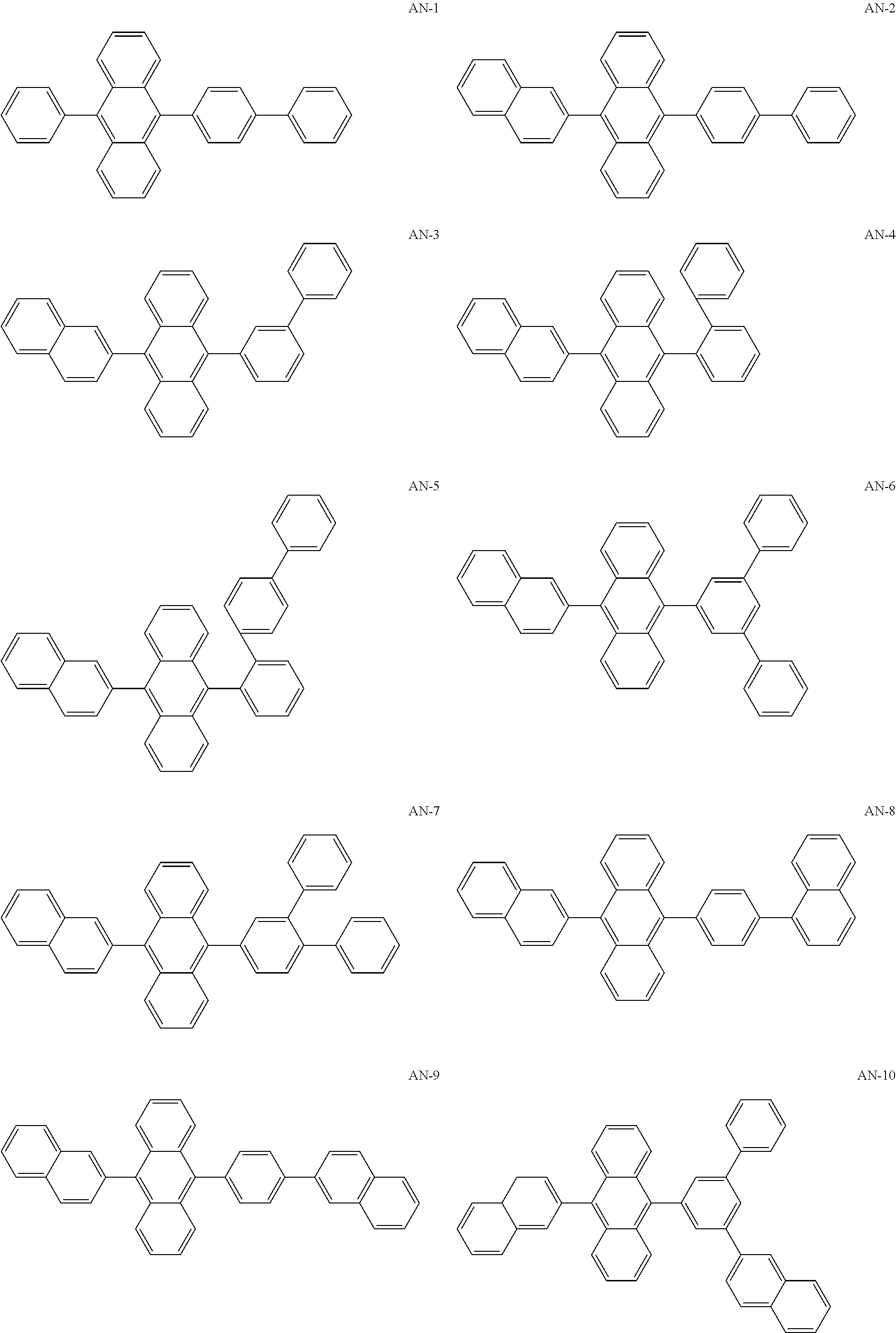

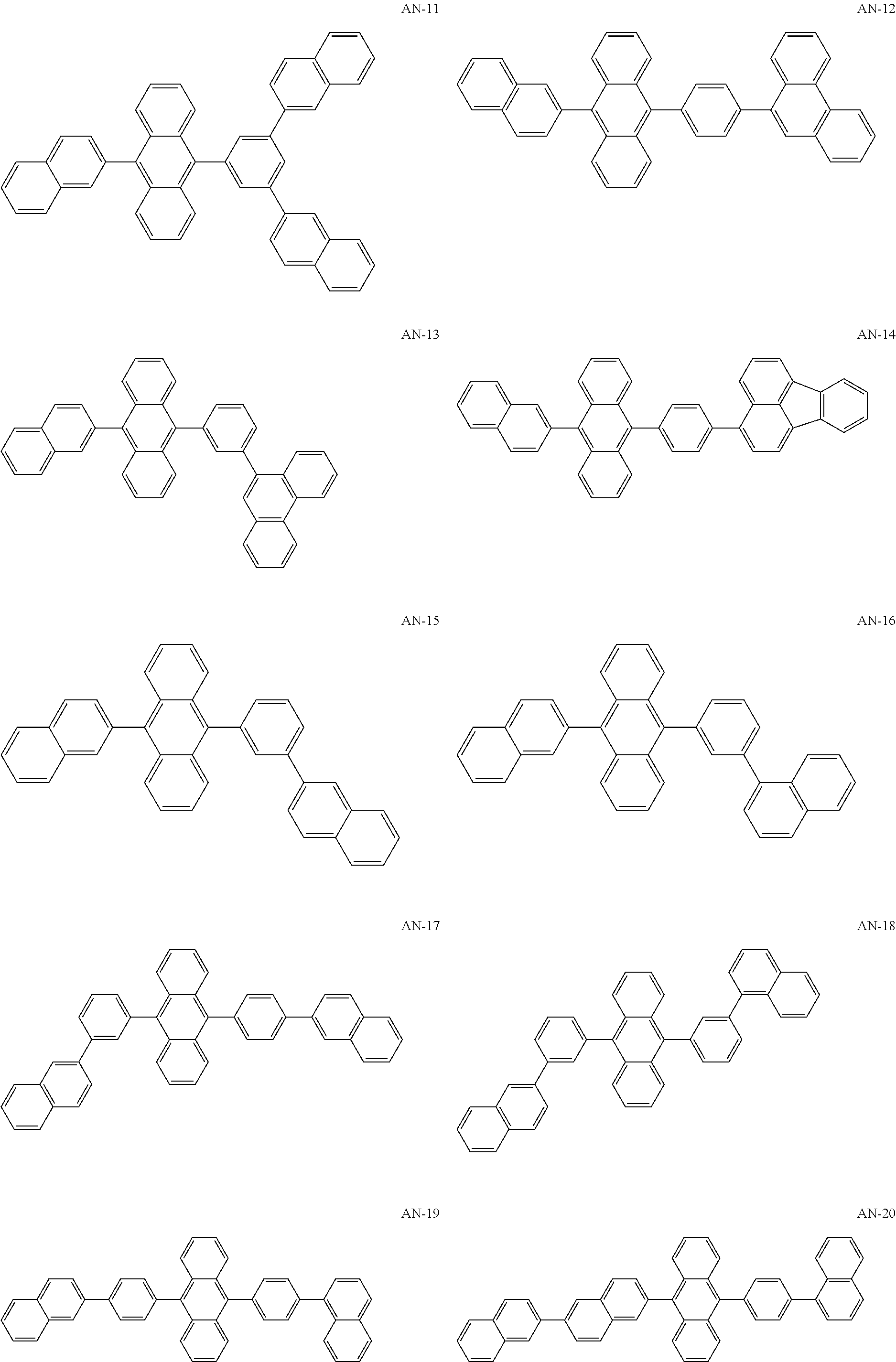

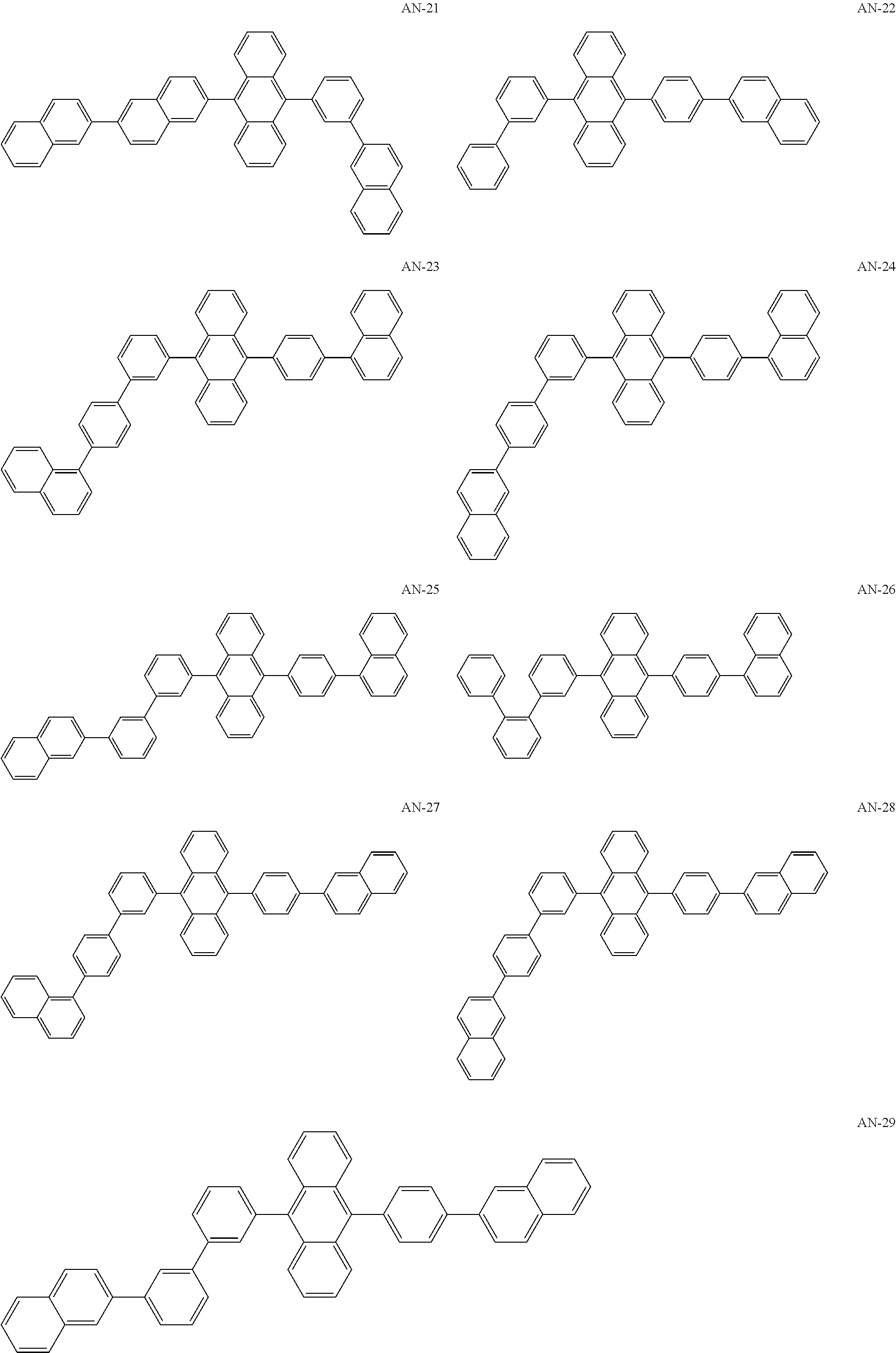

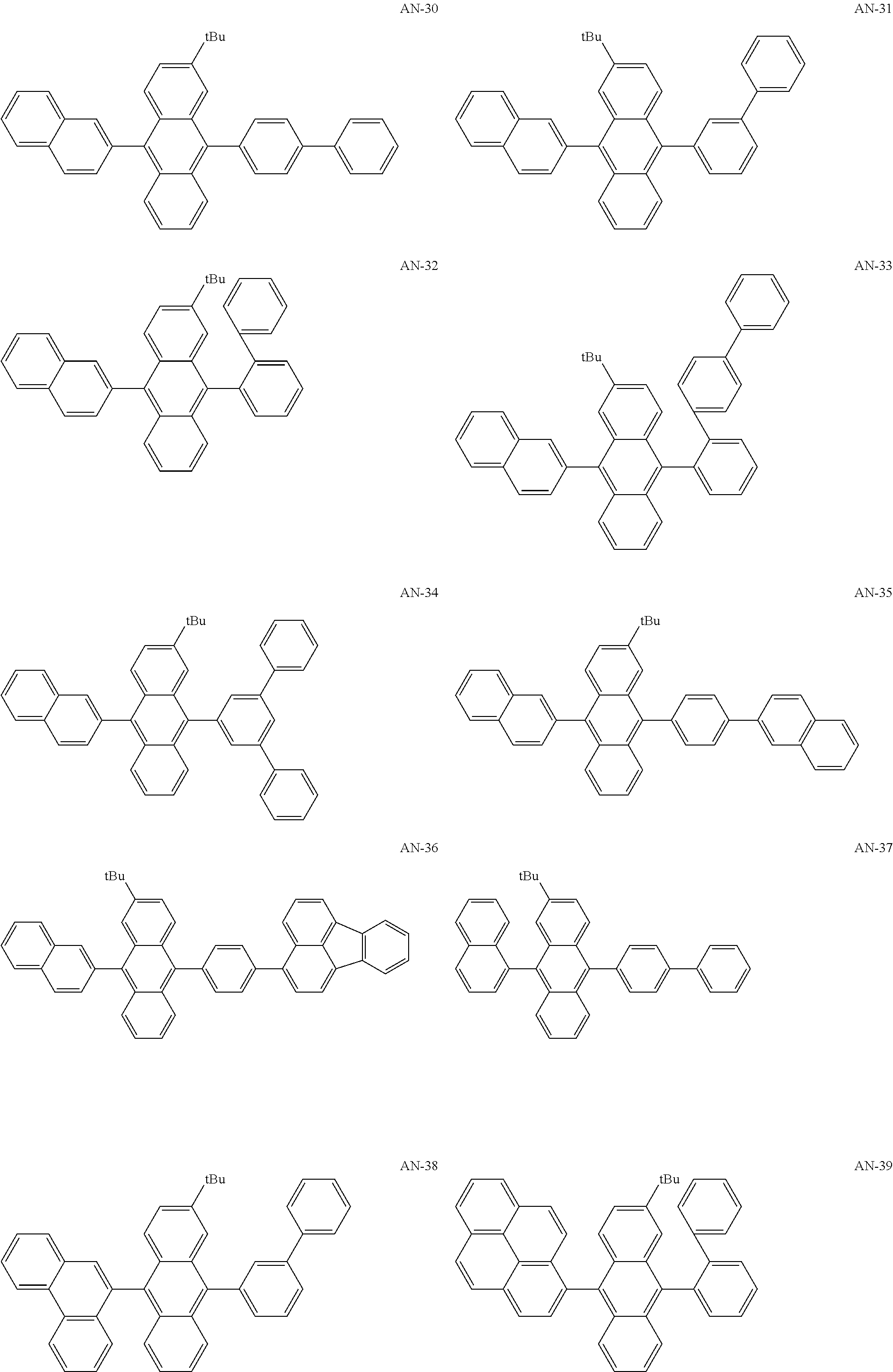

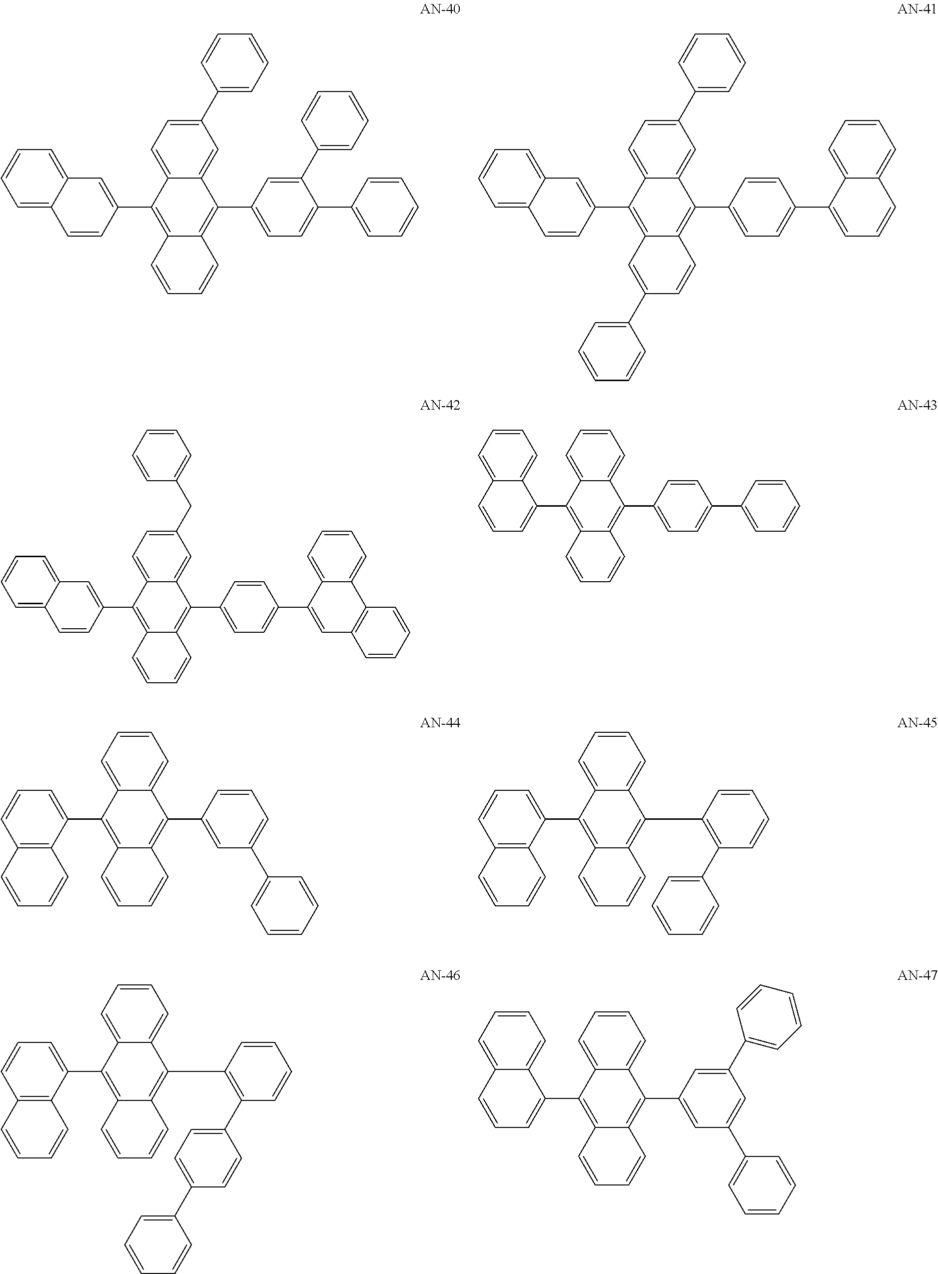

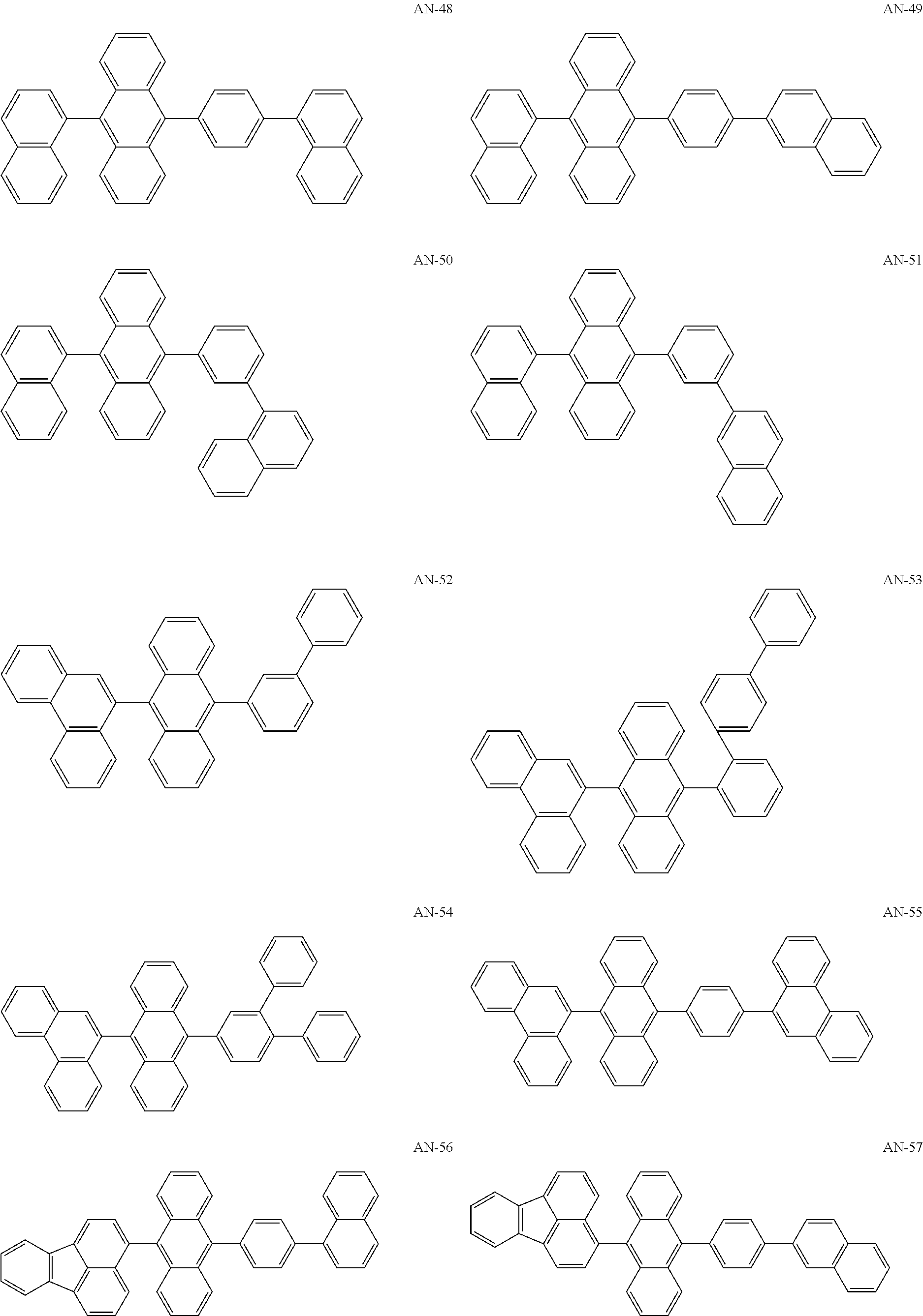

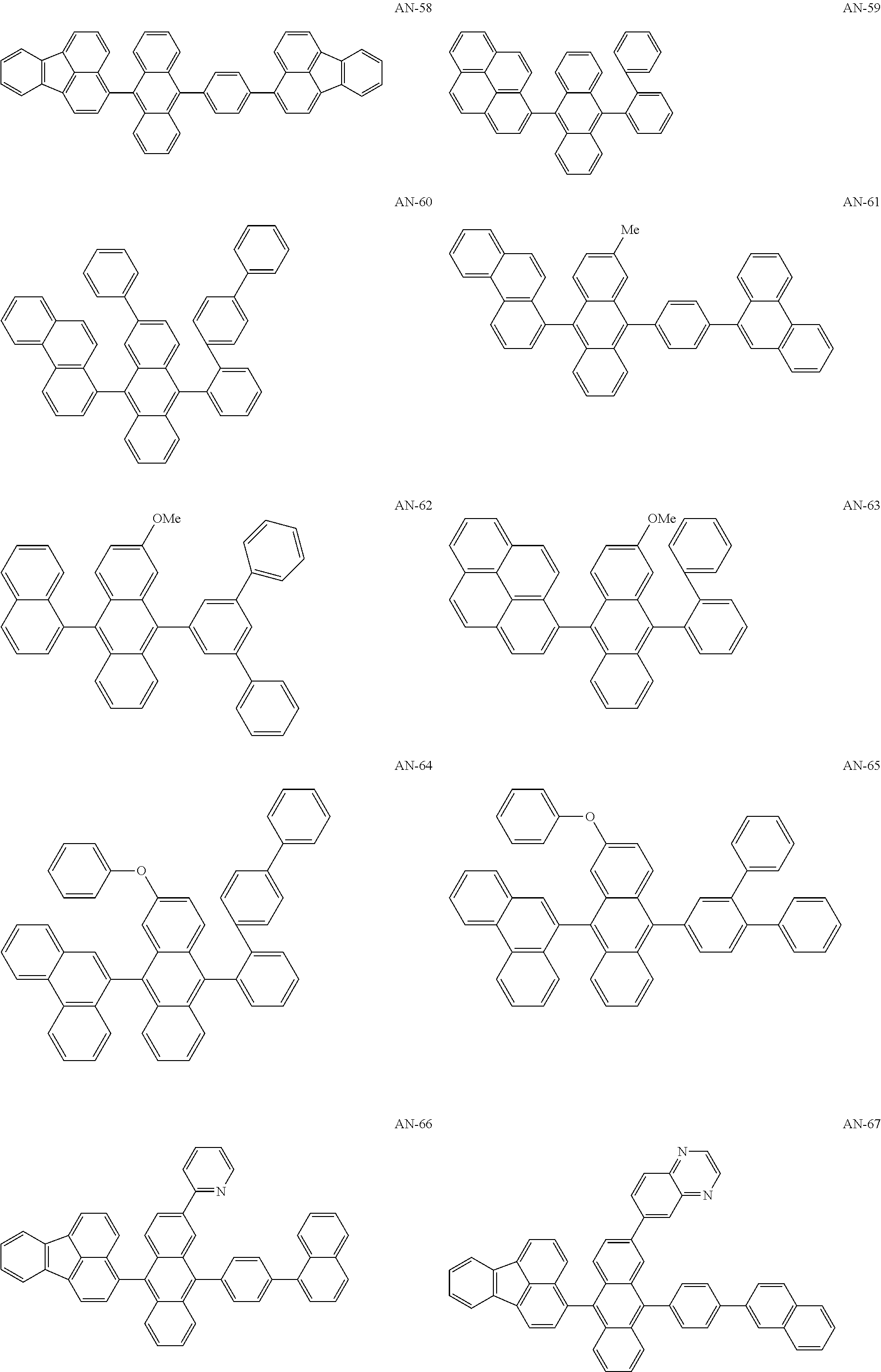

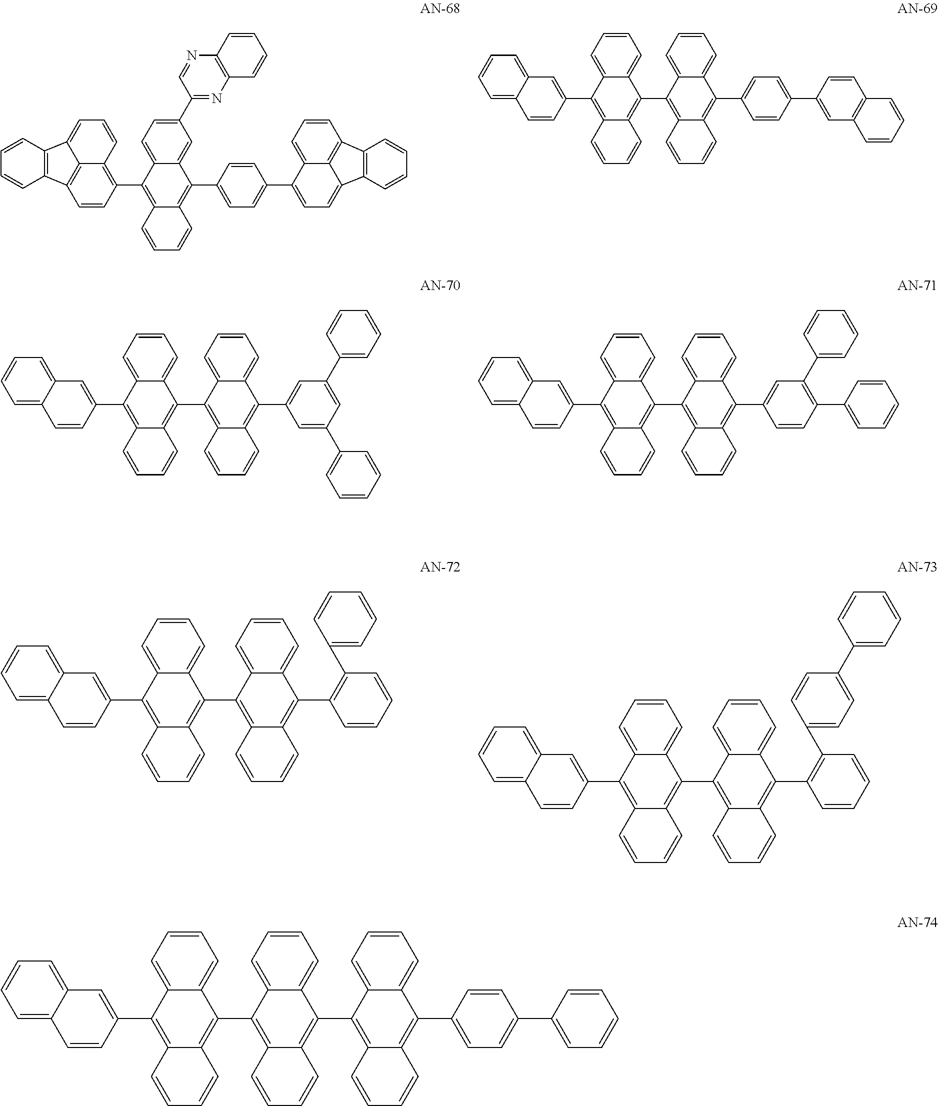

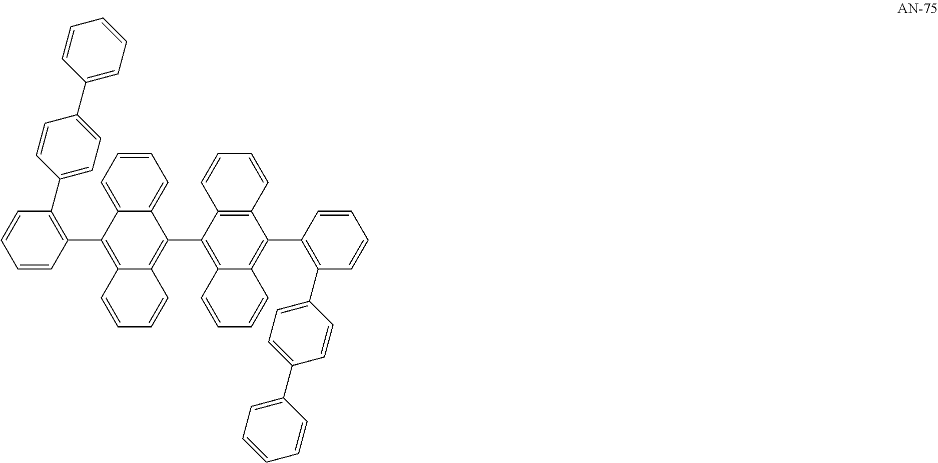

The organic EL material composition of the invention may further contain a dopant.

As the dopant, a styrylamine derivative represented by the following formula (8) or an arylamine derivative represented by the following formula (9) are preferable.

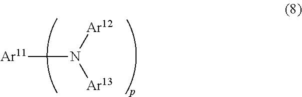

wherein Ar¹¹ is a residue corresponding to benzene, biphenyl, terphenyl, stilbene and distyrylarylene, Ar¹² and Ar¹³ are independently a hydrogen atom or an aromatic group having 6 to 20 carbon atoms, provided that Ar¹² to Ar¹³ may be substituted; p is an integer of 1 to 4. At least one of Ar¹¹ to Ar¹³ is a styryl group or a group having a styryl group.

As the aromatic group having 6 to 20 carbon atoms, a phenyl group, a naphthyl group, an anthracenyl group, a phenanthryl group, a terphenyl group or the like are preferable.

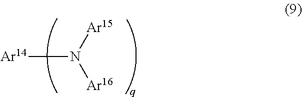

wherein Ar¹⁴ is a residue corresponding to a substituted or unsubstituted arene having 5 to 40 ring carbon atoms; Ar¹⁵ and Ar¹⁶ are independently an aryl group having 5 to 40 ring carbon atoms; and q is an integer of 1 to 4.

As the aryl group having 5 to 40 ring atoms, phenyl, naphthyl, anthracenyl, phenanthryl, pyrenyl, coronenyl, biphenyl, terphenyl, pyrrolyl, furanyl, thiophenyl, benzothiophenyl, oxadiazolyl, diphenylanthracenyl, indolyl, carbazolyl, pyridyl, benzoquinolyl, fluoranthenyl, acenaphthofluoranthenyl, stilbenyl or the like are preferable. The aryl group having 5 to 40 ring atoms may further be substituted with a substituent. As preferred substituents, alkyl groups having 1 to 6 carbon atoms (e.g. ethyl group, methyl group, isopropyl group, n-propyl group, s-butyl group, t-butyl group, pentyl group, hexyl group, cyclopentyl group and cyclohexyl group), alkoxy groups having 1 to 6 carbon atoms (e.g. ethoxy group, methoxy group, isopropoxy group, n-propoxy group, s-butoxy group, t-butoxy group, pentoxy group, hexyloxy group, cyclopentoxy group, and cyclohexyloxy group), aryl groups having 5 to 40 ring atoms, amino groups substituted with an aryl group having 5 to 40 ring atoms, ester groups containing an aryl group having 5 to 40 ring atoms, ester groups containing an alkyl group having 1 to 6 carbon atoms, a cyano group, a nitro group, and a halogen atom (e.g. chlorine, bromine, and iodine) can be given.

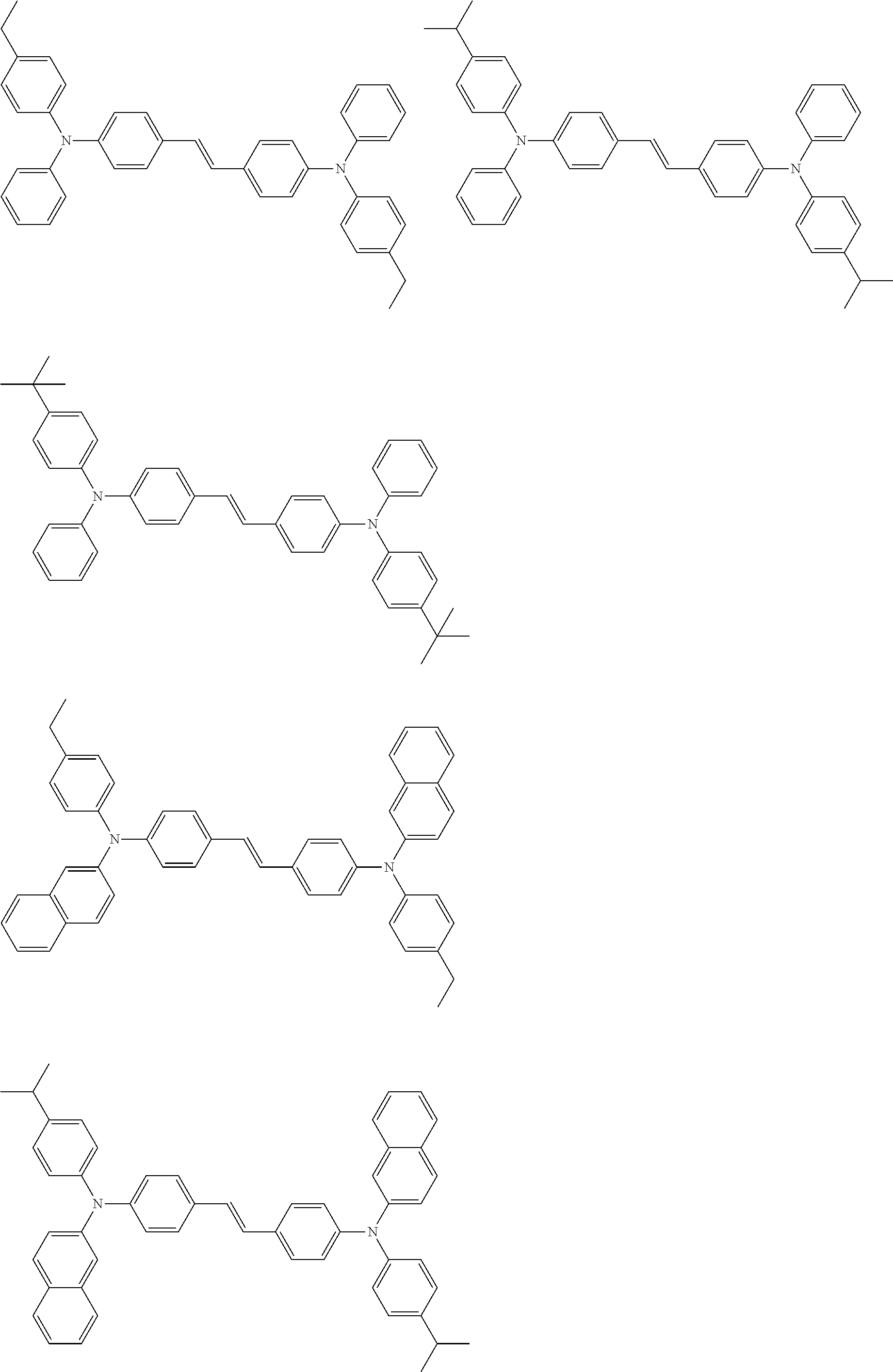

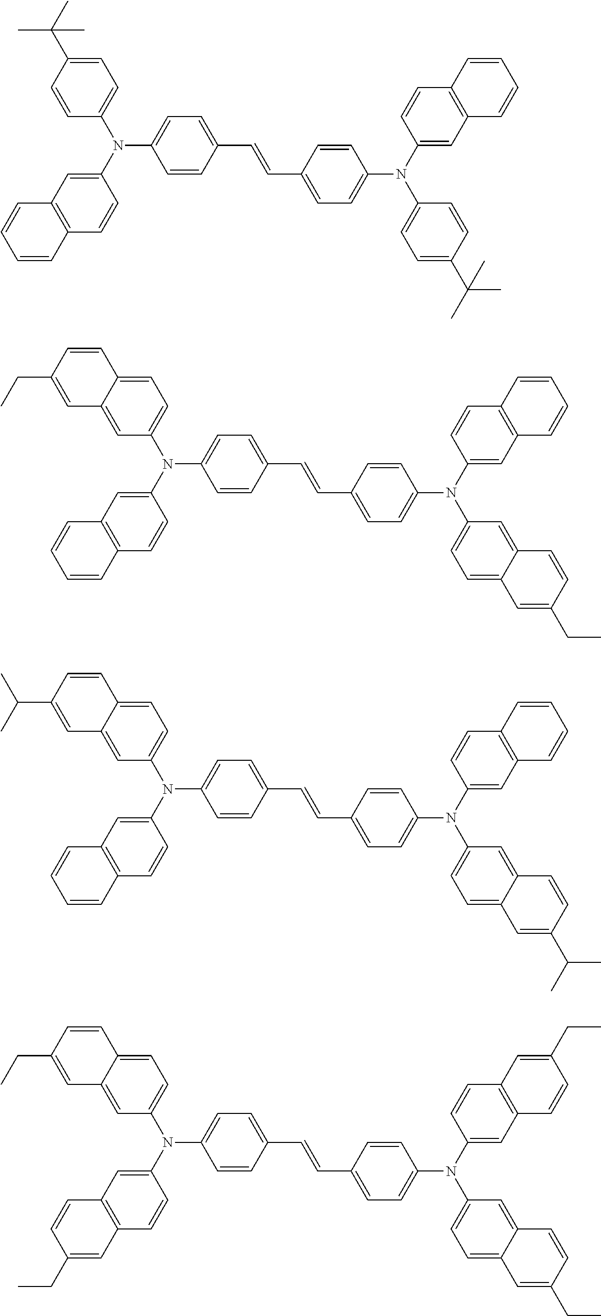

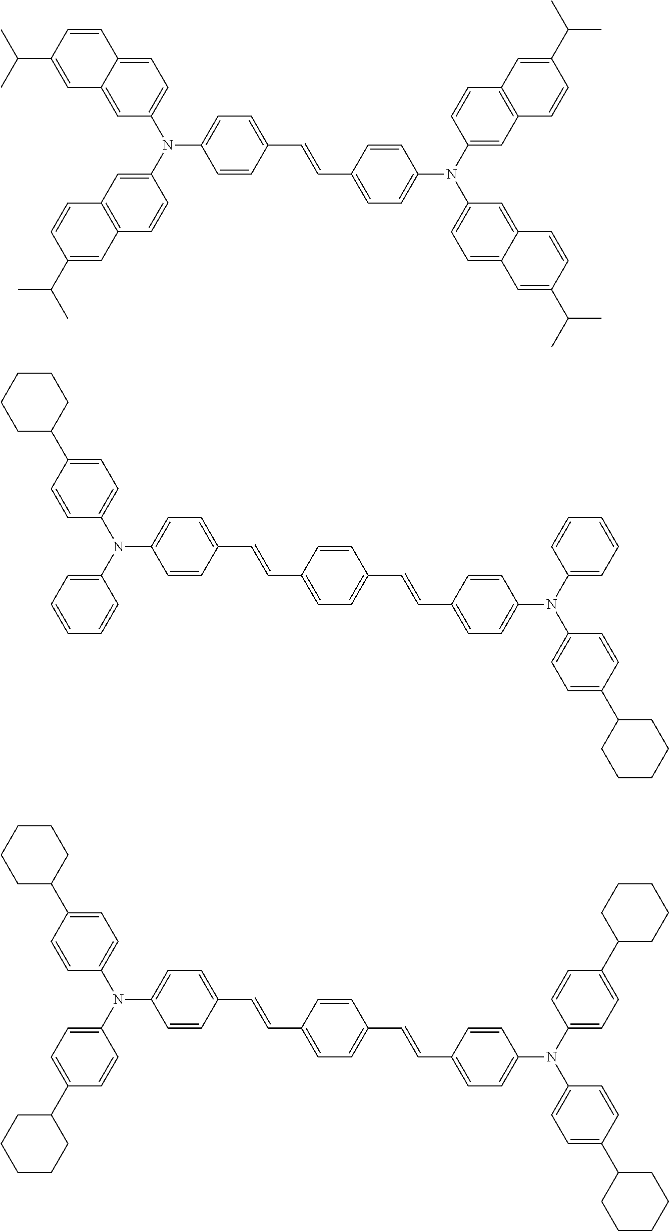

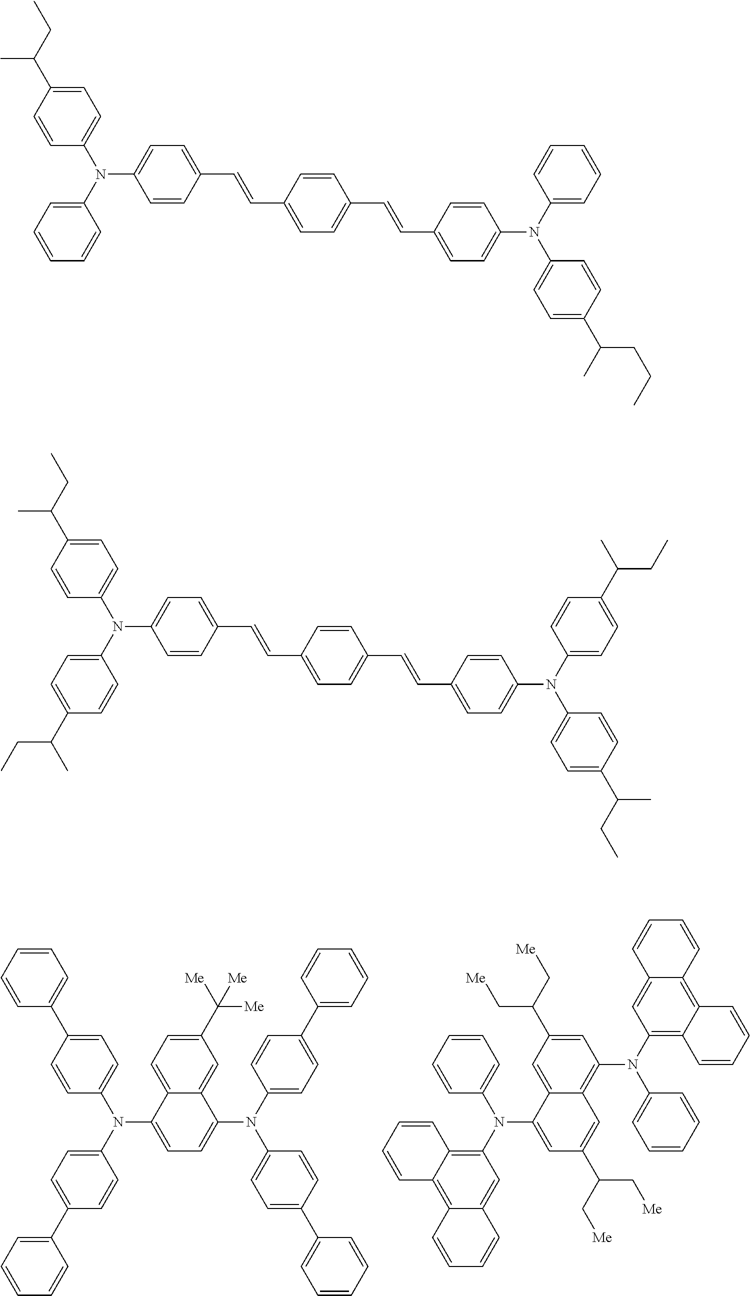

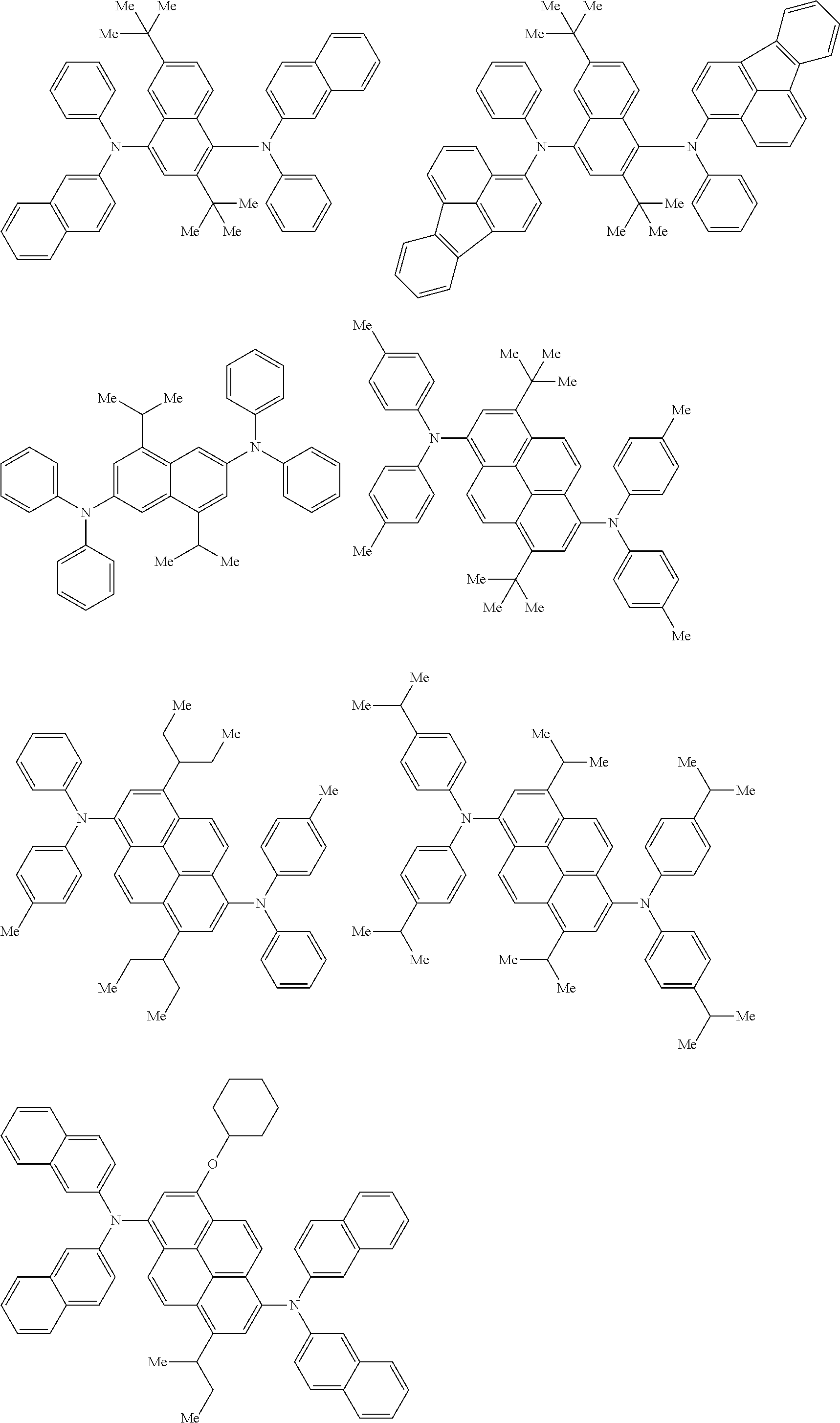

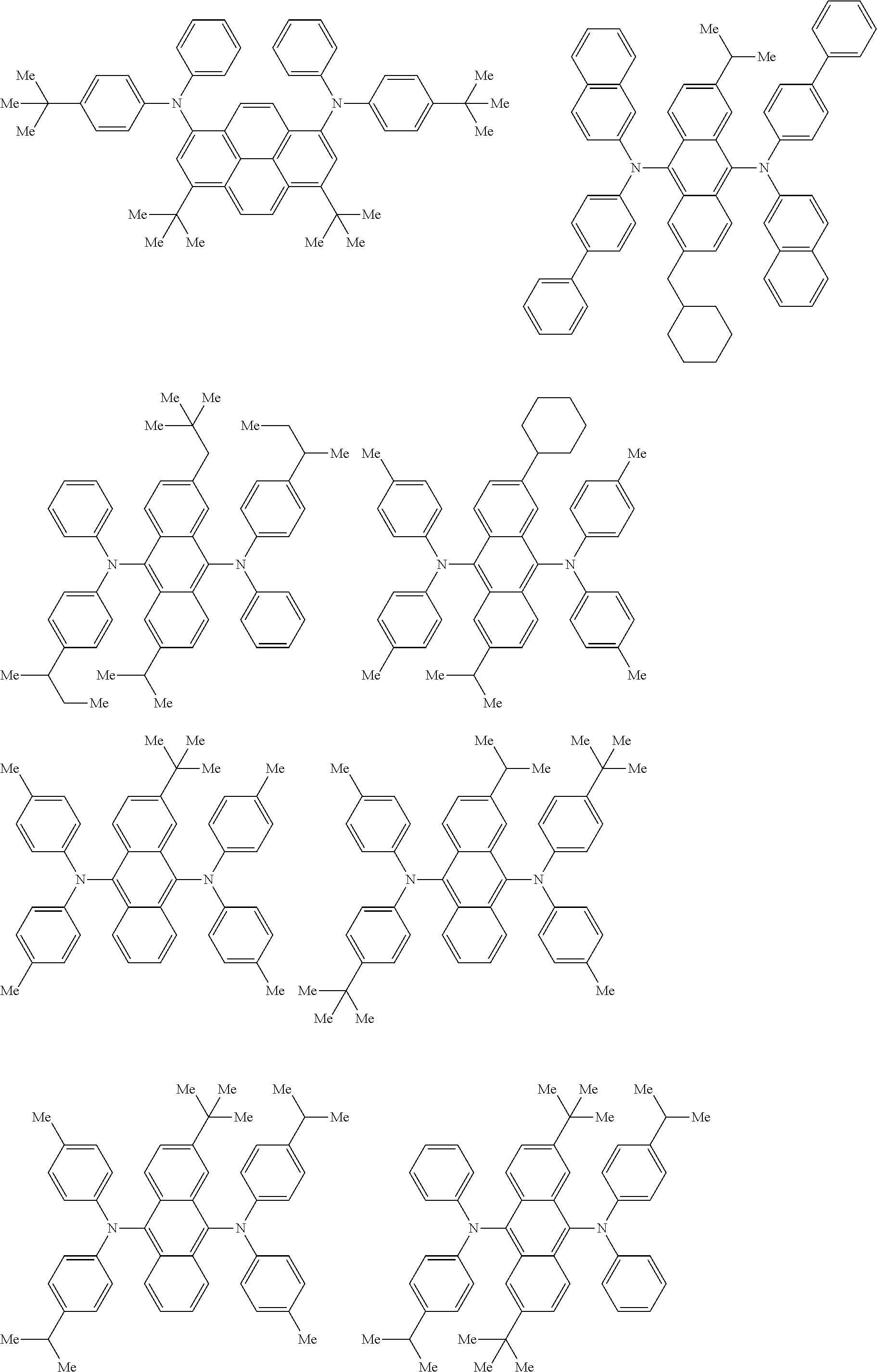

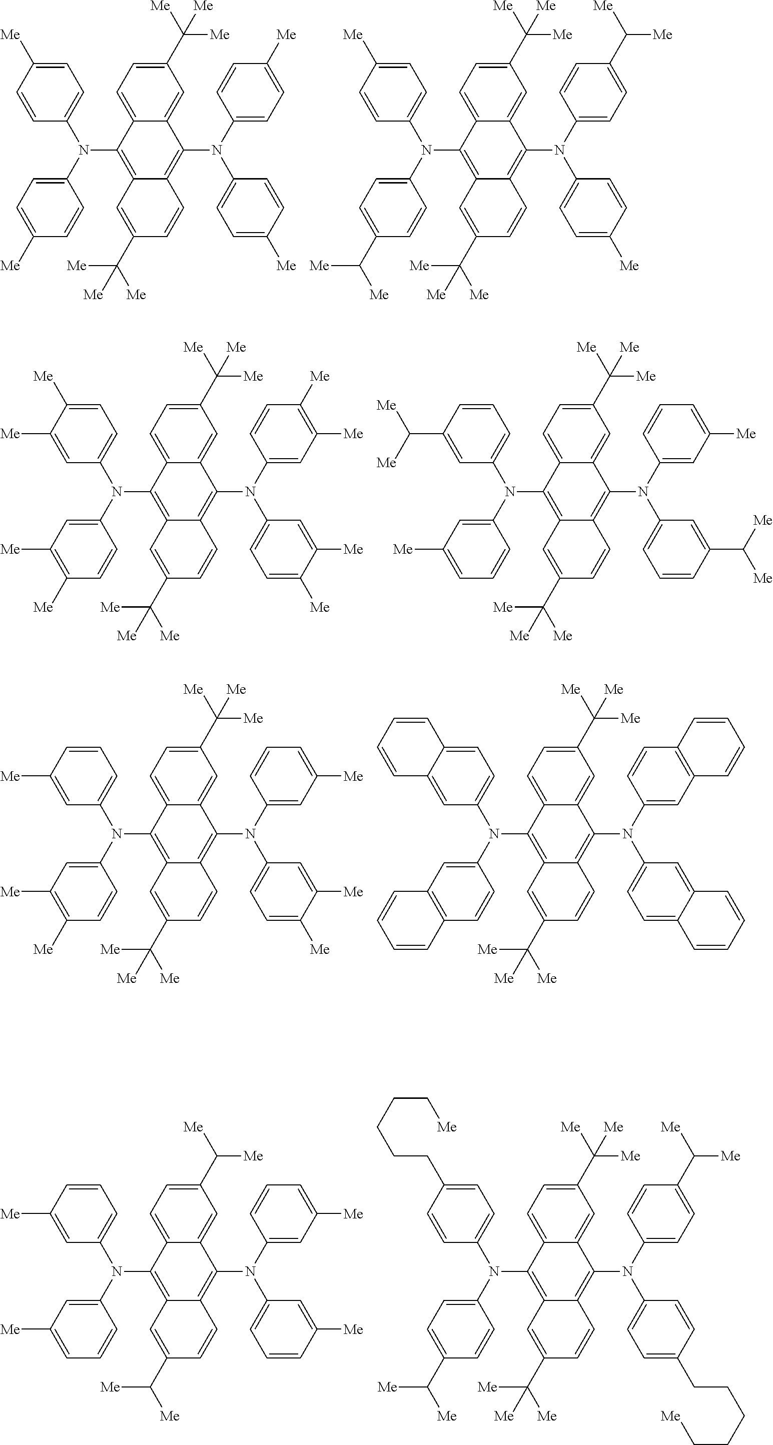

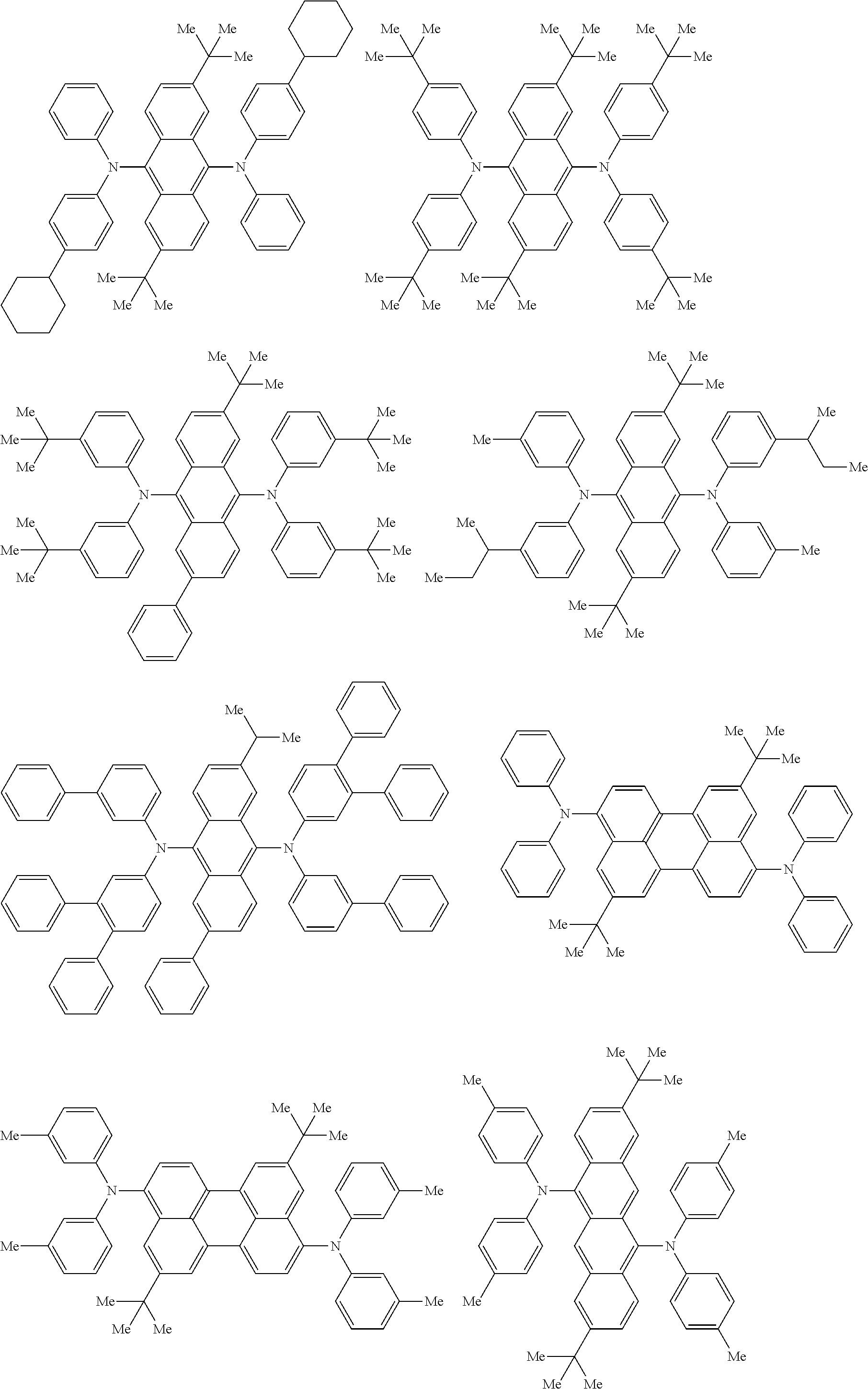

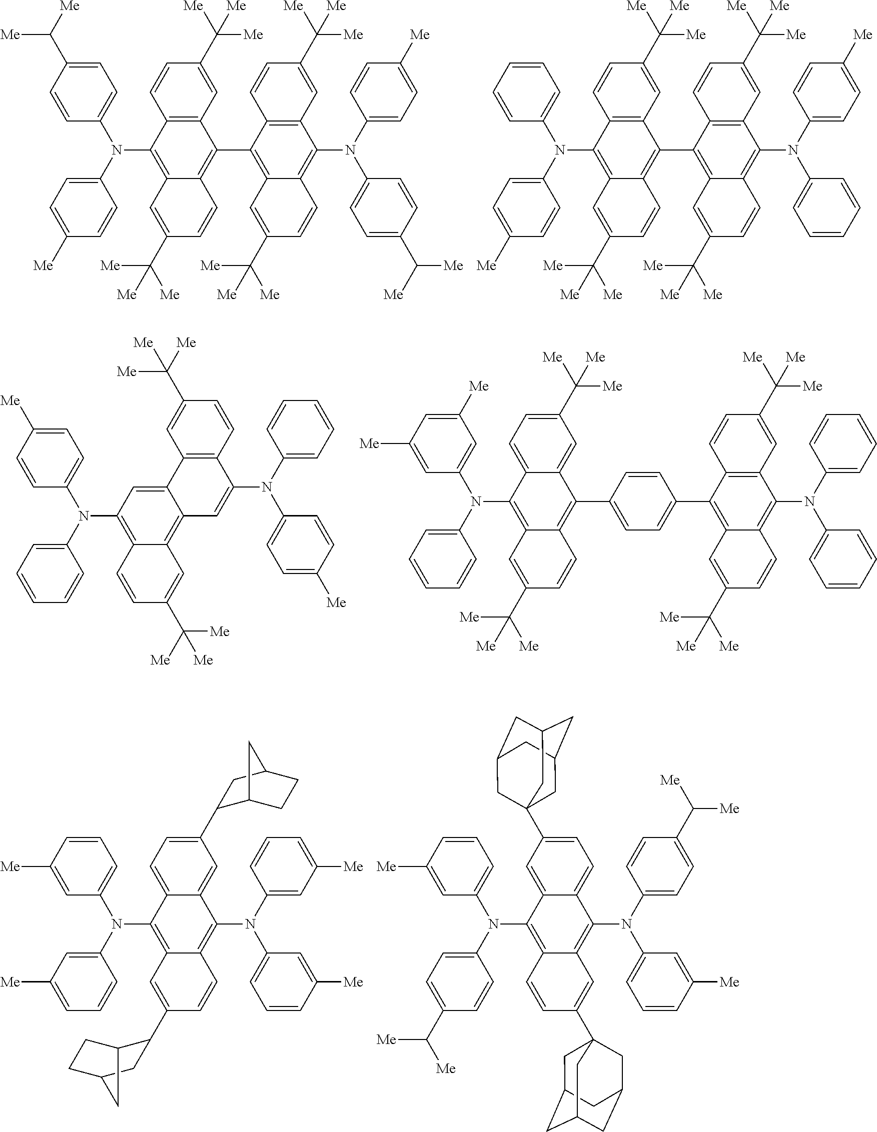

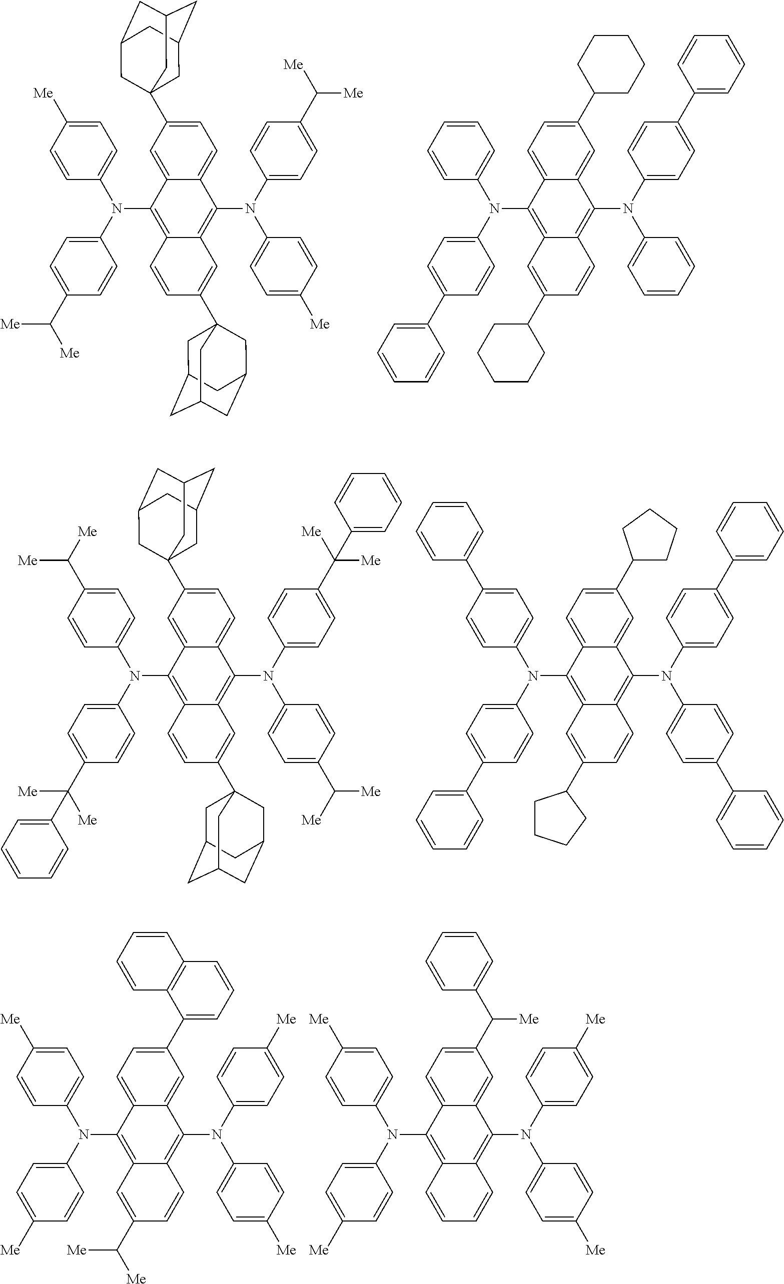

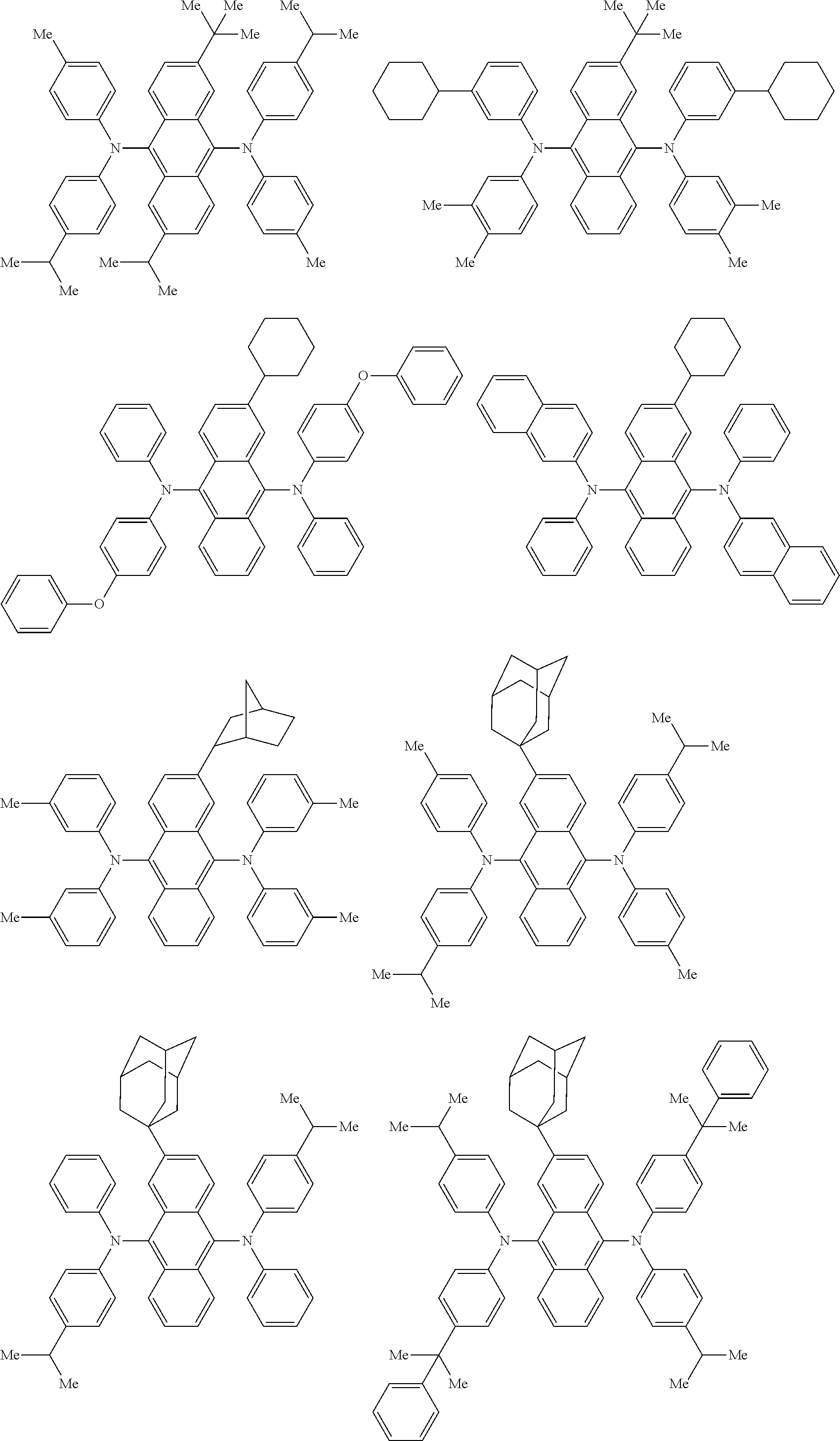

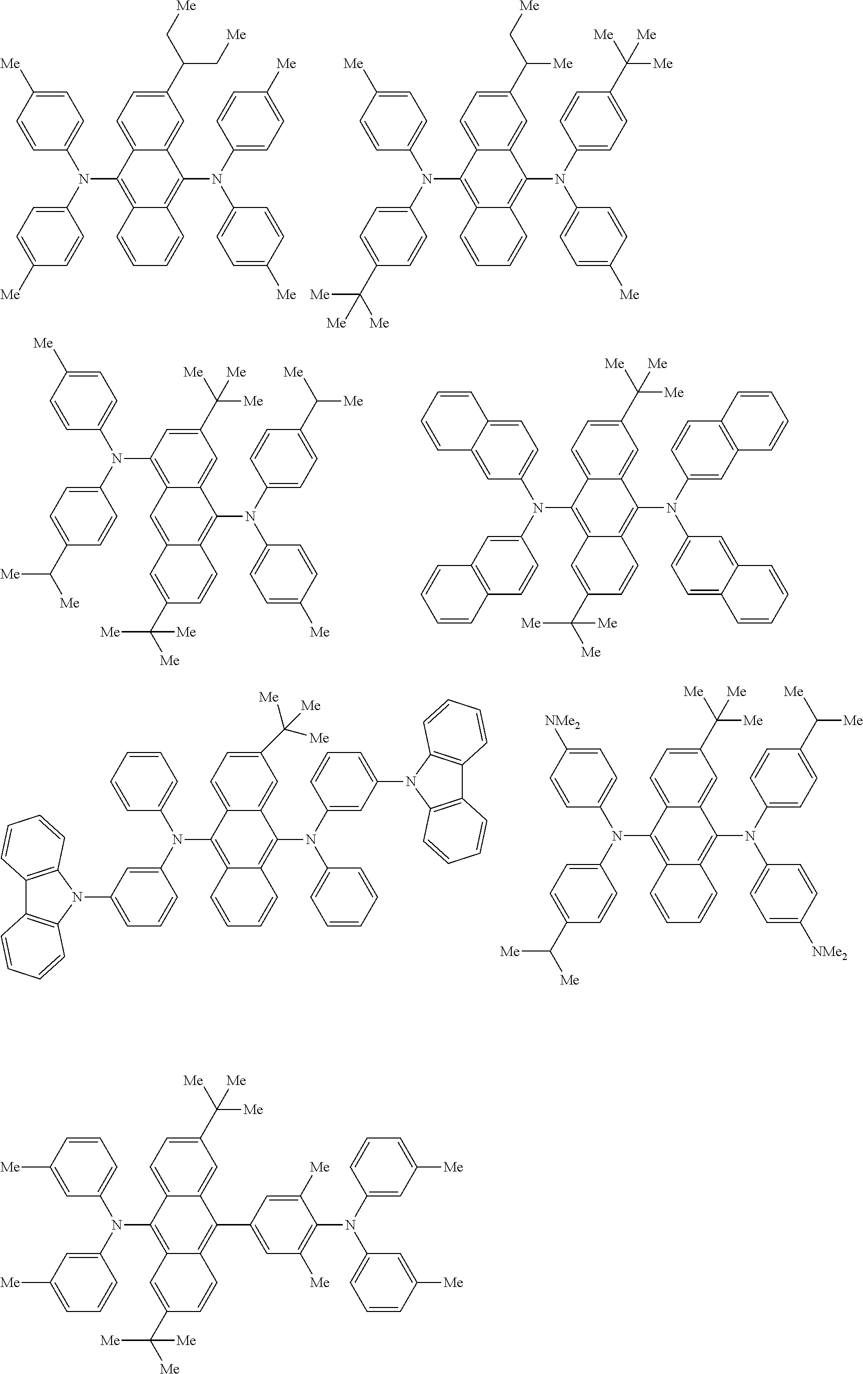

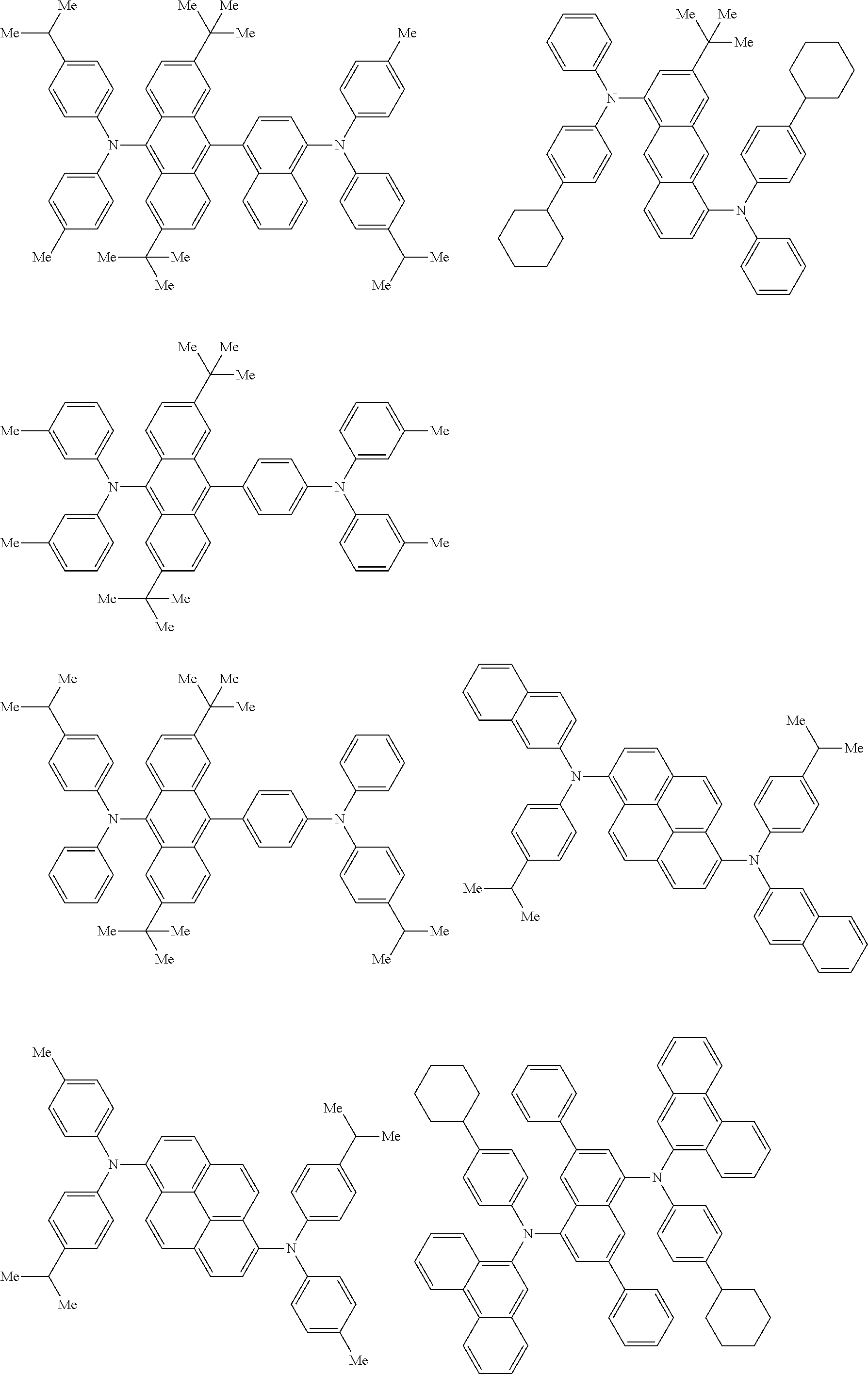

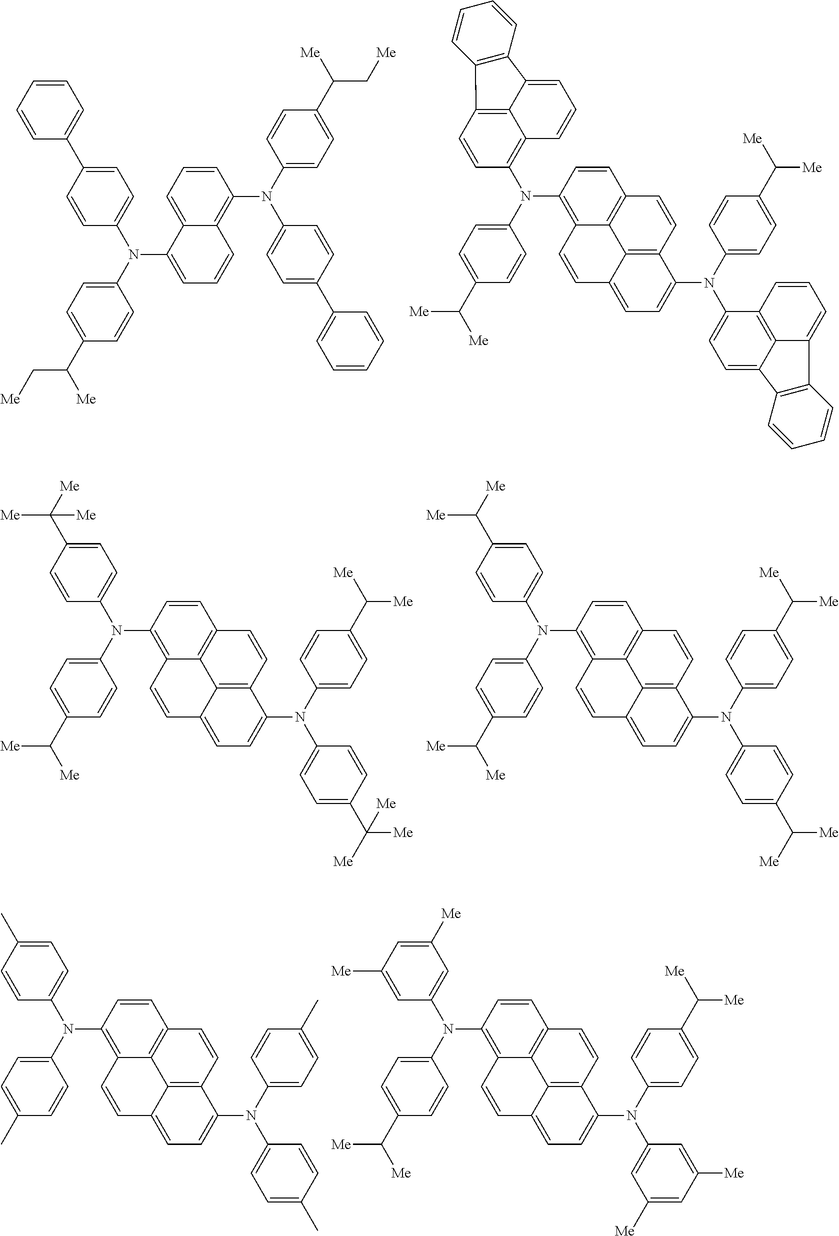

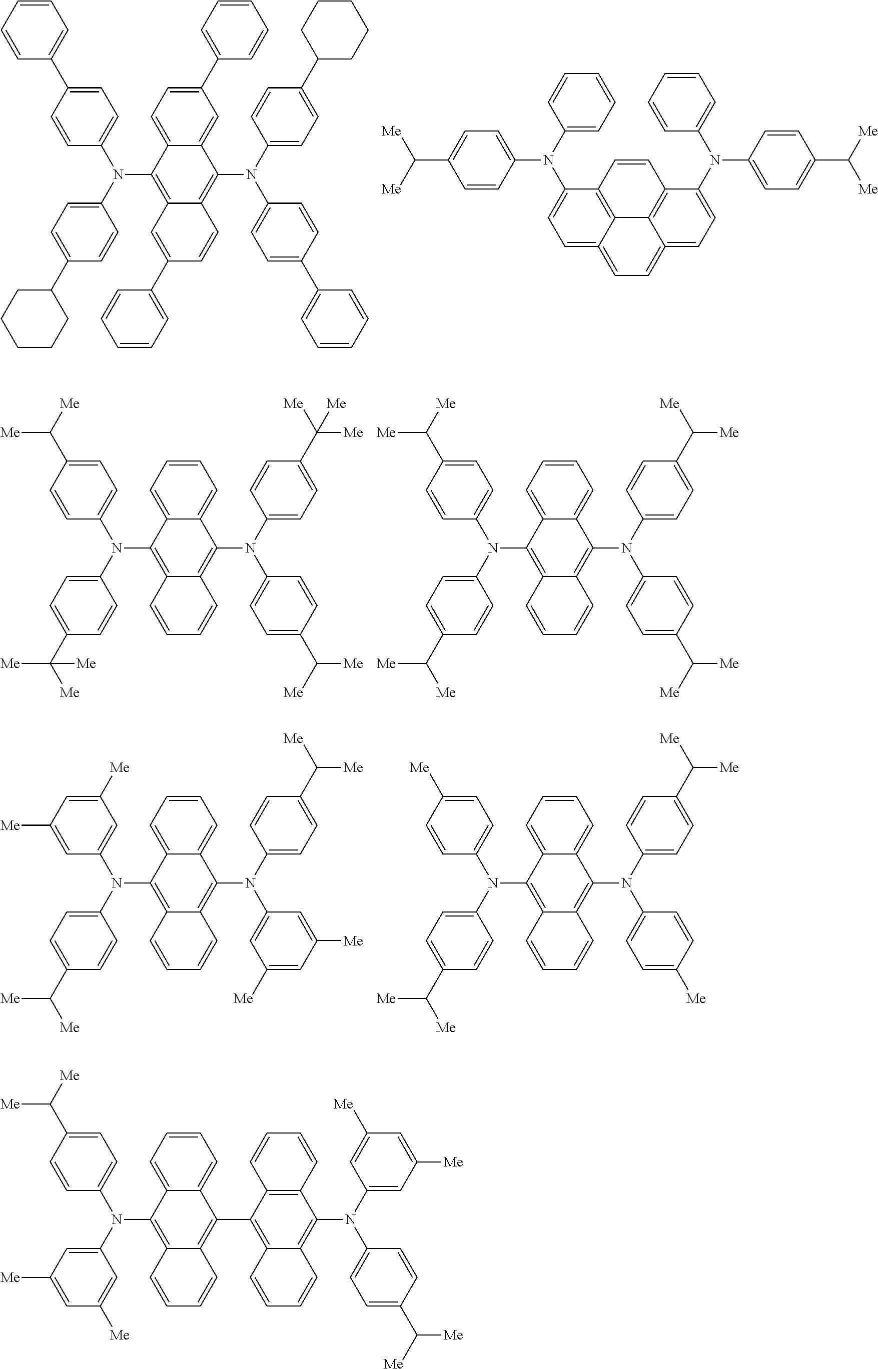

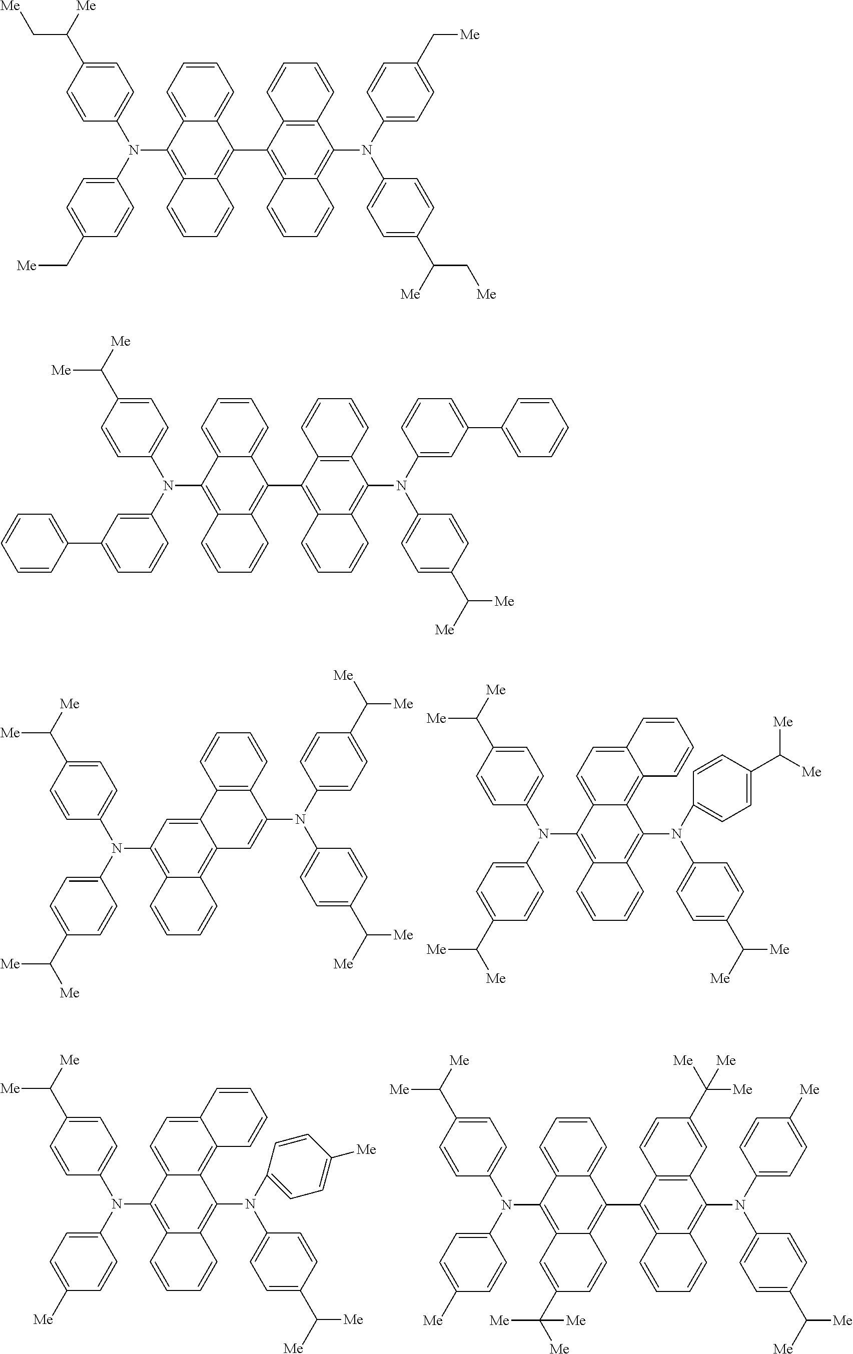

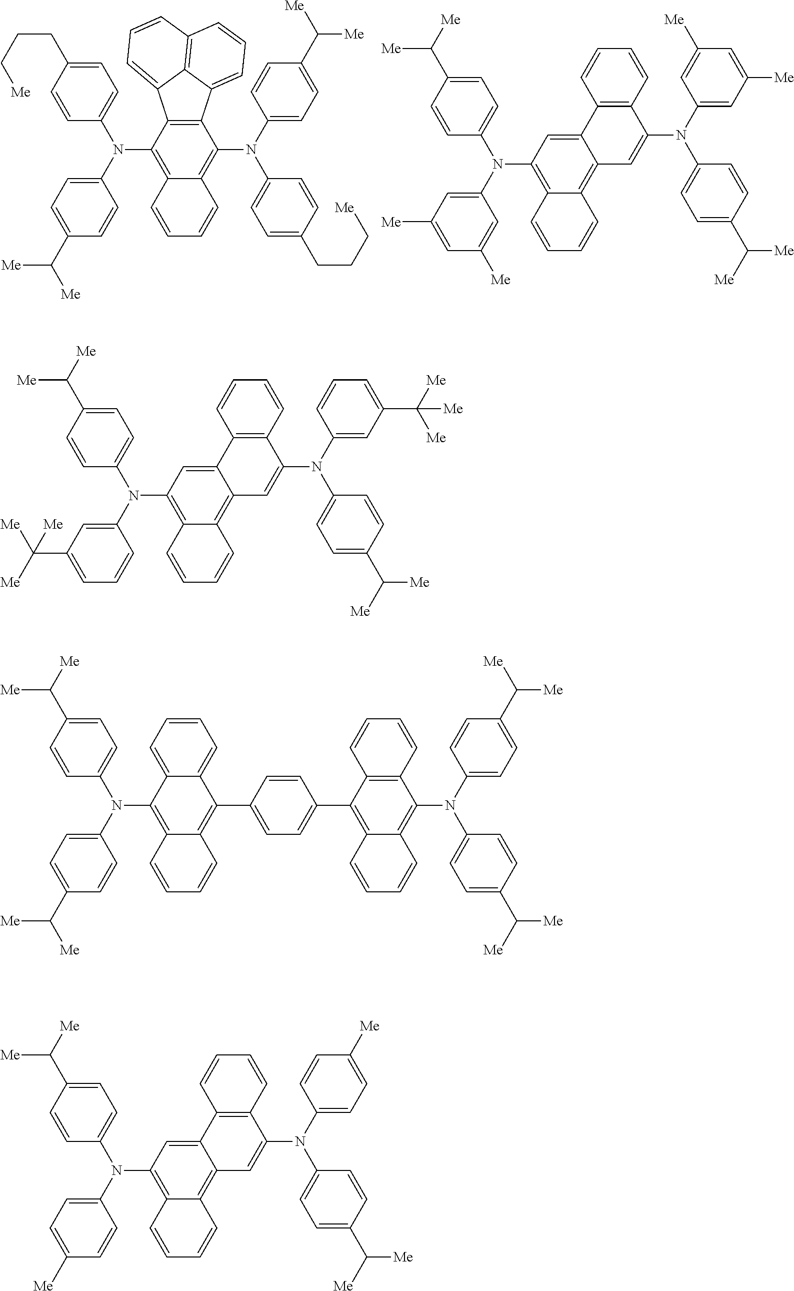

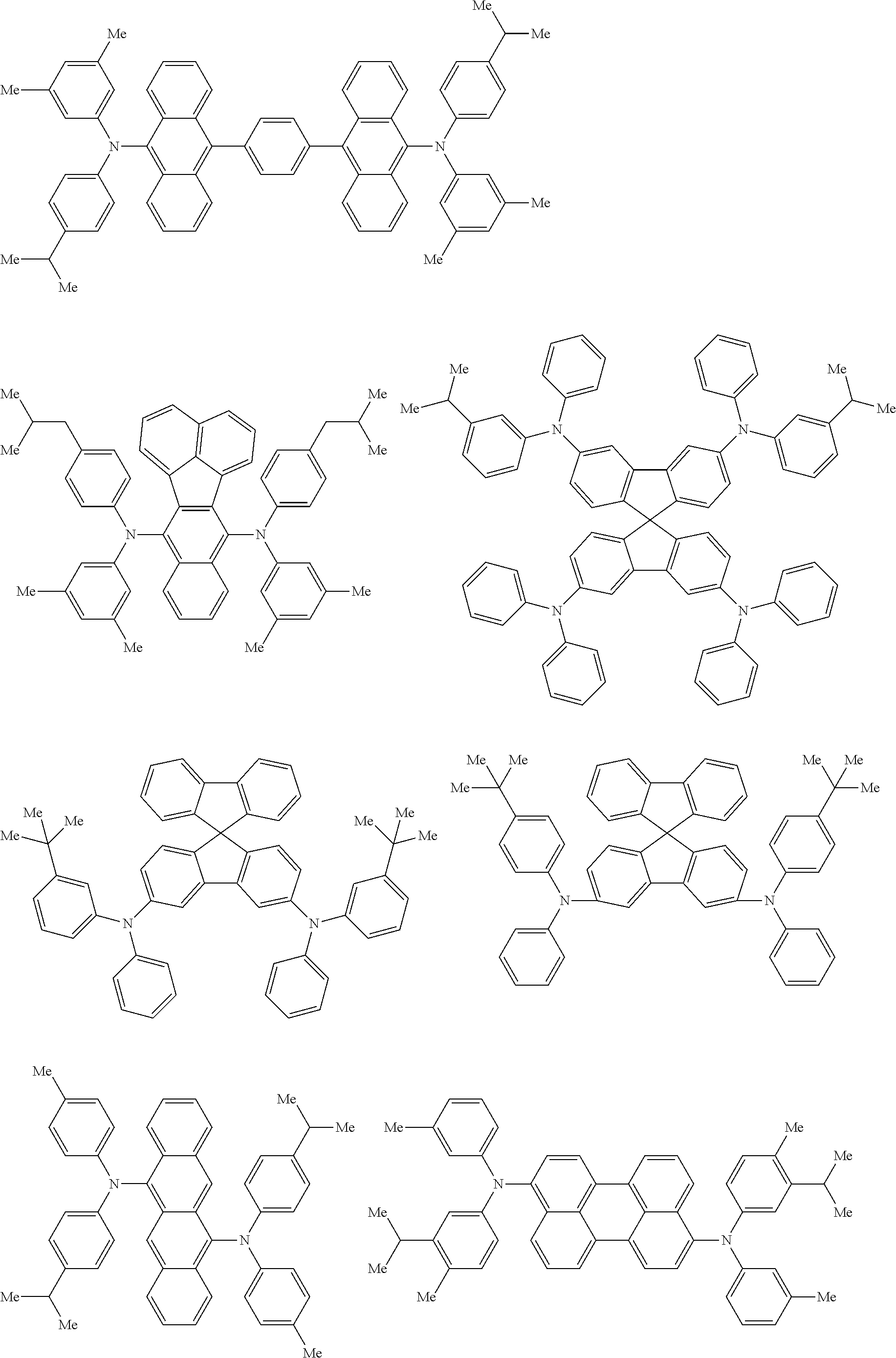

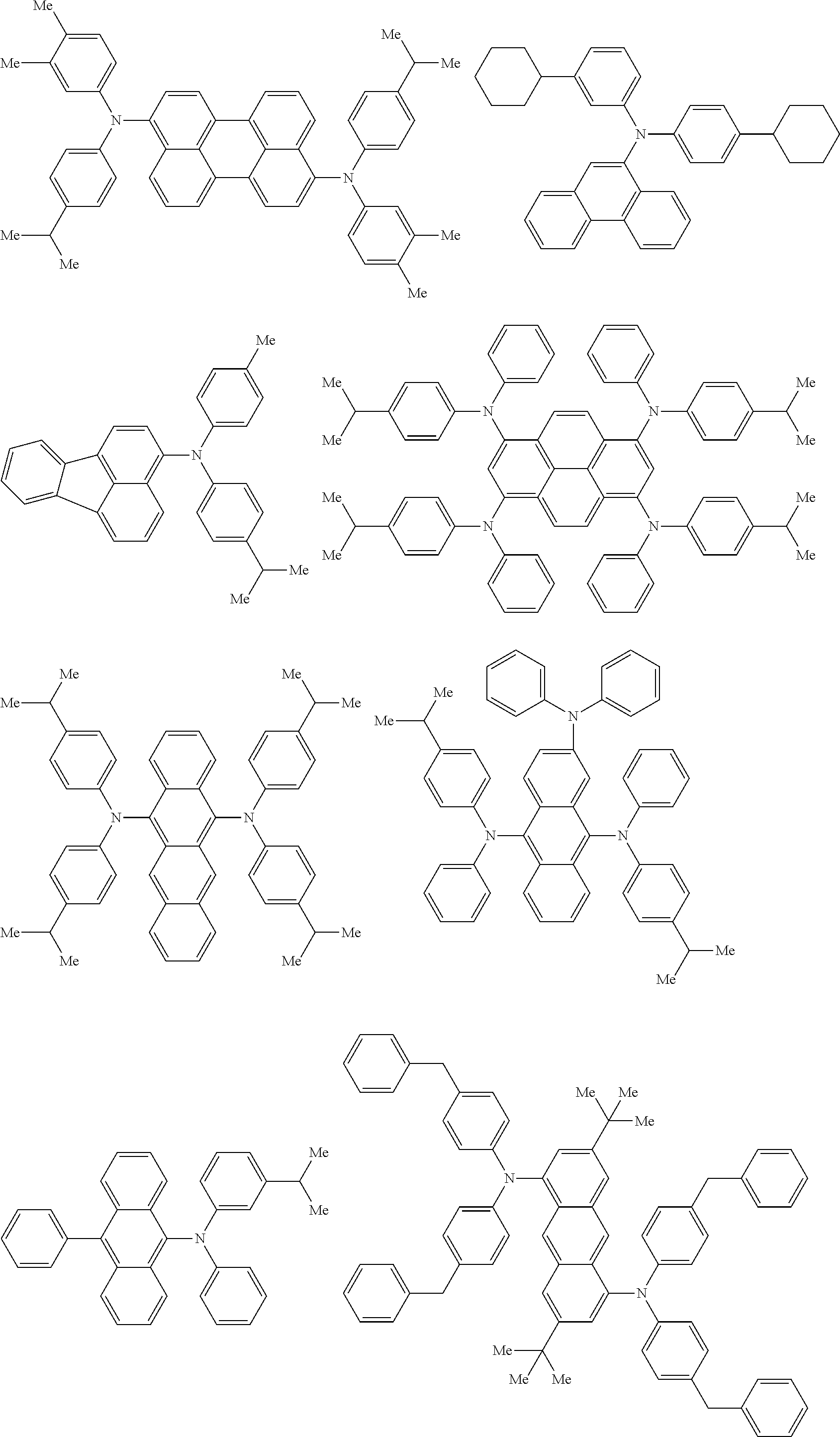

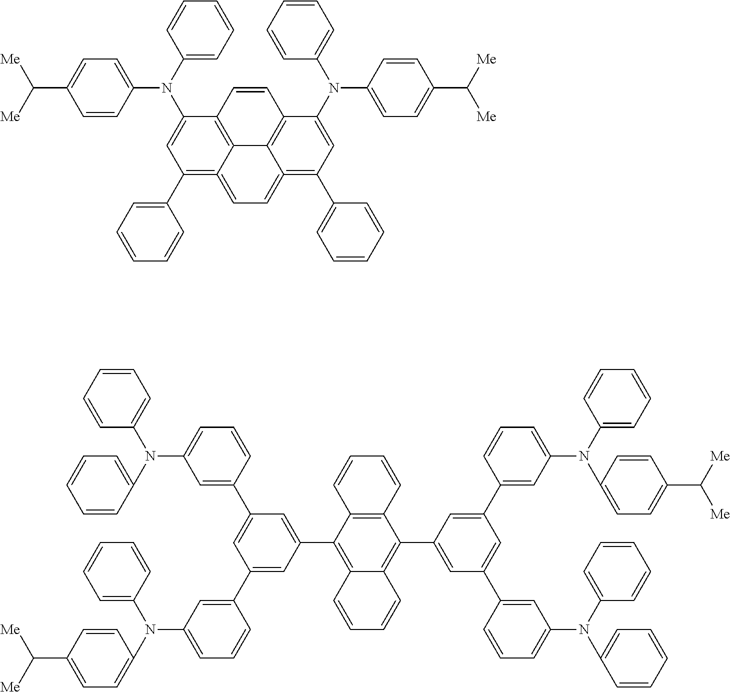

(In the formula, Me is a methyl group)

In the organic EL material composition of the invention, the concentration by weight (derivative x 100/solvent) of an anthracene derivative is preferably 0.01 wt % or more. The emitting layer is formed of a host, or a host and a dopant. Since a host constitutes a large part of the emitting layer, if the concentration of a host is significantly low, it is impossible to form the emitting layer into a predetermined film thickness. Therefore, if the concentration is lower than 0.01 wt %, it may be hard to form the composition into a film with a uniform thickness.

The thickness of the organic thin film layer of an organic EL device is normally 10 to 100 nm. In many cases, the thickness of the organic thin film layer is about 50 nm. If the film thickness is smaller than 50 nm, problems such as lowering of emission performance or significant shift in color tone may occur. In order to form easily a film with a thickness of 50 nm or more, it is preferred that the concentration of an anthracene derivative be 0.05 wt % or more.

If the organic EL material composition contains a dopant, it is preferred that the content of the dopant be 0.01 to 20 wt % of a host material.

In the organic EL material composition of the invention, if necessary, a viscosity adjusting agent, an antioxidant, a light stabilizer, a polymerization inhibitor, a surface tension adjustment agent, a filler, a surfactant, an antifoaming agent, a leveling agent, an antistatic agent or the like may be added.

For example, as a viscosity adjusting liquid, an alcohol-based solution, a ketone-based solution, a paraffin-based solution and an alkyl-substituted aromatic compound-based solution or the like can be given.

An alcohol-based solution and an alkyl-substituted aromatic compound-based solution are preferable.

Examples of an alcohol-based solution include methanol or ethanol, propanol, butanol, pentanol, hexanol, octanol, nonanol, decanol, cyclohexanol, methylcellosolve, ethylcellosolve, ethylene glycol, propanediol, butanediol and benzyl alcohol. The above-mentioned alcohol may have a linear structure or a branched structure.

As the alkyl-substituted aromatic compound-based solution, linear or branched butylbenzene, dodecylbenzene, tetraline, cyclohexylbenzene, 1,1-bis(3,4-dimethylphenyl)ethane or the like can be given.

As the antioxidant, L-ascorbic acid (vitamin C), erythorbic acid (isoascorbic acid), catechin, tocopherol (vitamin E), BHT (dibutylhydroxytoluene), BHA (butylhydroxyanisole), sodium sulfite, sulfur dioxide, or the like can be given. Further, it is preferable to have a functional group selected from a group consisting of a phenol group, an aldehyde group, a phosphino group, a phosphite group, a thiol group, a dithio group, an amino group and an imino group.

As the light stabilizer (HALS), in respect of the function thereof, those having a function of converting light energy to thermal energy or those having a radical scavenging function can be given, for example. Light stabilizers, having the above-mentioned functions, have an effect of suppressing a lowering in fluorescent quantum yield or an effect of improving the stability of chromaticity. Of these light stabilizers, those having a radical scavenging function are particularly superior in the effect of improving these properties. Specifically, a hindered amine-based light stabilizer is preferable. Of these hindered amine-based light stabilizers, an alkoxyamine-based or an acetylated amine-based hindered amine-based light stabilizer is preferable.

A viscosity adjusting agent, an antioxidant, a light stabilizer, a polymerization inhibitor, a surface tension adjustment agent, a filler, a surfactant, an antifoaming agent, a leveling agent, an antistatic agent or the like, which are as mentioned above, may be used singly or may be used in combination with a plurality of additives differing in function or may be used in combination with a plurality of additives having the same function.

The composition of the invention may be composed essentially of a solvent, an anthracene derivative, and, optionally, a dopant. The composition of the invention may consist only of these components. The expression “composed essentially of” means that the above-mentioned composition is mainly composed of a solvent, an anthracene derivative, and, optionally, a dopant, and may contain the above-mentioned additives in addition to these components.

The organic EL material composition to be used in a coating method is required to contain an organic EL material in an amount equal to or larger than a predetermined amount, and is required to have a predetermined viscosity.

If an organic EL thin film is formed by a coating method such as spin coating, ink jetting and nozzle printing, the solution is required to have a viscosity of several cP or more.

If the organic EL material composition is used in the ink-jet method, the viscosity of the solution is more preferably 6 cP or more, with 7 cP or more being further preferable.

Although no particular restrictions are imposed on the upper limit of the viscosity as long as the solution can form a thin film with a thickness of several 10 nm, a viscosity of about 100 cP can be given, for example.

If film formation is conducted by using the slit coating method or the like, the viscosity of the solution is preferably several cP or less, with 3 cP or less being more preferable.

As for the organic EL material composition, it is preferred that a solid or powdery material having a size of 0.5 μm or more, more preferably 0.2 μm or more, be not mixed in a coating liquid.

There are no particular restrictions on the method for preparing the organic EL material composition of the invention as long as it is a method by which the above-mentioned raw materials of the composition can be mixed and dissolved or dispersed in a solvent.

It is preferable to prepare by the heating method, the reflux heating method, the pressure method, the agitation method, the ultrasonic irradiation method, the electromagnetic irradiation method, the beads mill dispersion method, the jet mill dispersion method, the oscillation method, or a combination of two or more of these.

The method for forming a thin film according to the invention will be explained.

In the method for forming a thin film according to the invention, the organic EL material composition as mentioned above is applied to a base to form a film thereon, followed by removal of a solvent, thereby to form a thin film.

As for the base, a substrate of an organic EL device, a substrate on which organic thin film layers such as a hole-injecting layer, electrodes or the like are formed, or the like can be given.

No particular restrictions are imposed on the method for applying and forming into a film of the organic EL material composition. Known coating methods, such as the dipping method, the spin coating method, the casting method, the gravure coating method, the bar coating method, the slit coating method, the roll coating method, the dip coating method, the spray coating method, the screen printing method, the flexographic printing method, the offset printing method, the inkjet printing method and the nozzle jet printing method, can be used.

After forming a film by the above-mentioned method, a thin film is formed by removing a solvent. It is preferred that a solvent be removed by natural drying, drying by heating, drying under pressure or under reduced pressure, gas flow drying, or by combination of these.

There are no particular restrictions on the thickness of the resulting thin film. In general, if the film thickness is too small, defects such as pinholes tend to occur easily, and if the film thickness is too large, a high voltage is required to be applied, resulting in a poor efficiency. Normally, the film thickness is preferably several nm to 1 μm. The film thickness can be adjusted by controlling the content of an anthracene derivative in the composition, the viscosity of the composition or the like.

Next, an explanation is made on the organic EL device of the invention.

The organic EL device of the invention comprise an anode and a cathode, and one or more organic thin film layers comprising an emitting layer between the anode and the cathode. At least one of the organic thin film layers is a thin film obtained by the forming method as mentioned above.

As the organic thin film layers of the organic EL device, a hole-injecting layer, a hole-transporting layer, an emitting layer, an electron-transporting layer, an electron-injecting layer or the like can be mentioned. It is preferred that these organic thin film layers be stacked. In the invention, it suffices that at least one layer of the organic thin film layers be a thin film formed by using the organic EL material composition of the invention as mentioned above. As for other constituting elements of the organic EL device such as a substrate, an electrode and organic thin film layers, there are no particular restrictions, and known materials can be used. Regarding the device structure, a known structure can be used.

In particular, it is preferred that the emitting layer be a thin film formed by using the composition of the invention.

The emitting layer is formed of a host material, or a combination of a host material and a dopant material. If a dopant is added, energy transfer or the like from the host material to the dopant material occurs, whereby the dopant material has a function of light emission.

By producing an organic EL device by using the composition of the invention, performance (luminous efficiency, life time, color purity or the like) of the organic EL device can be improved. In particular, the composition changes only slightly with the passage of time. An increase in water content of the composition, an increase in oxygen amount of the composition, precipitation of an organic EL material which is dissolved or the like can be suppressed. As a result, deterioration of device performance caused by the storage of the composition can be suppressed.

### EXAMPLES

The invention will be explained hereinbelow in detail with reference to the Examples, which should not be construed as limiting the scope of the invention. The structures of the anthracene derivative (host) and the dopant used in the Examples or the like are shown below.

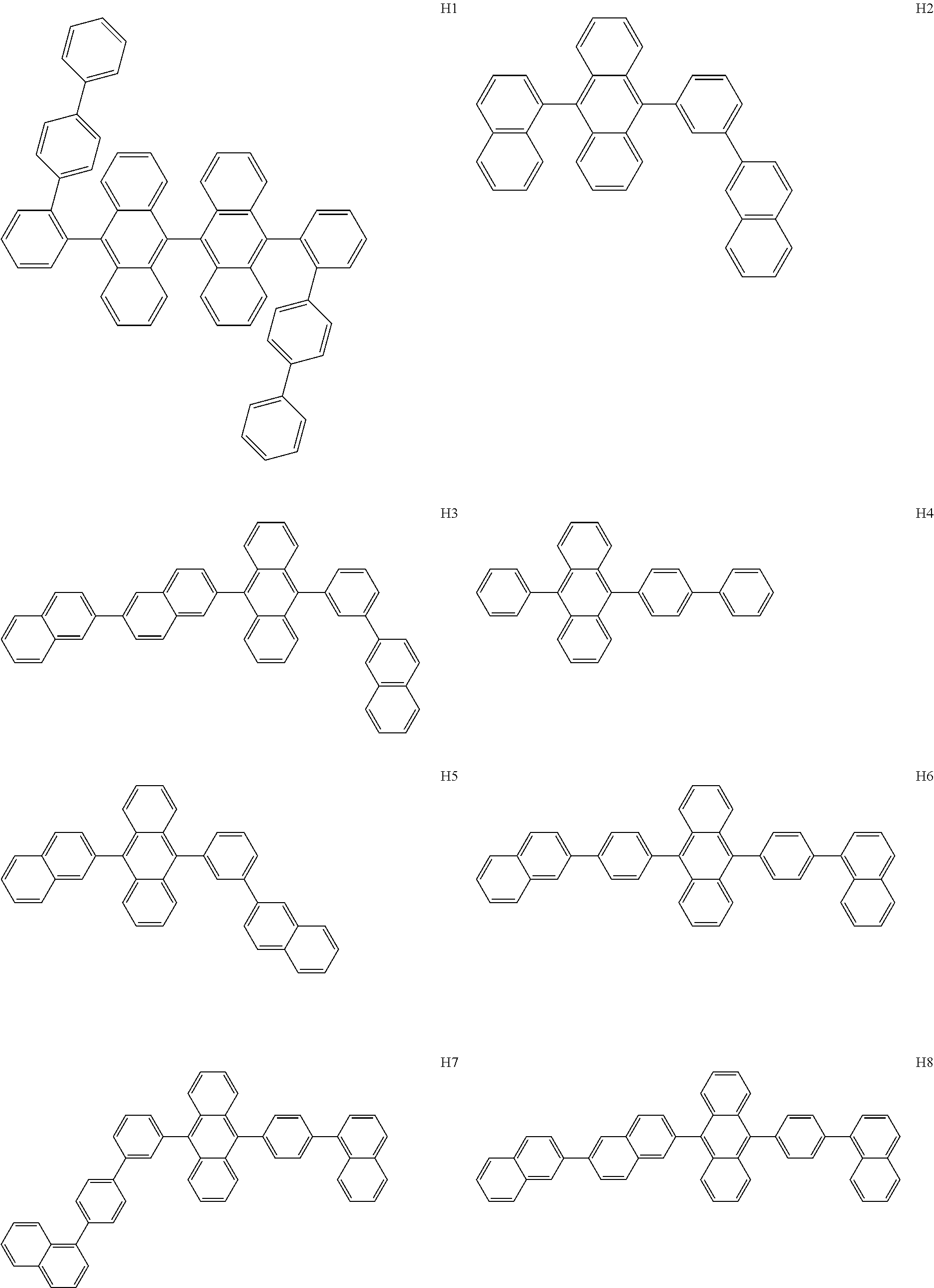

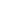

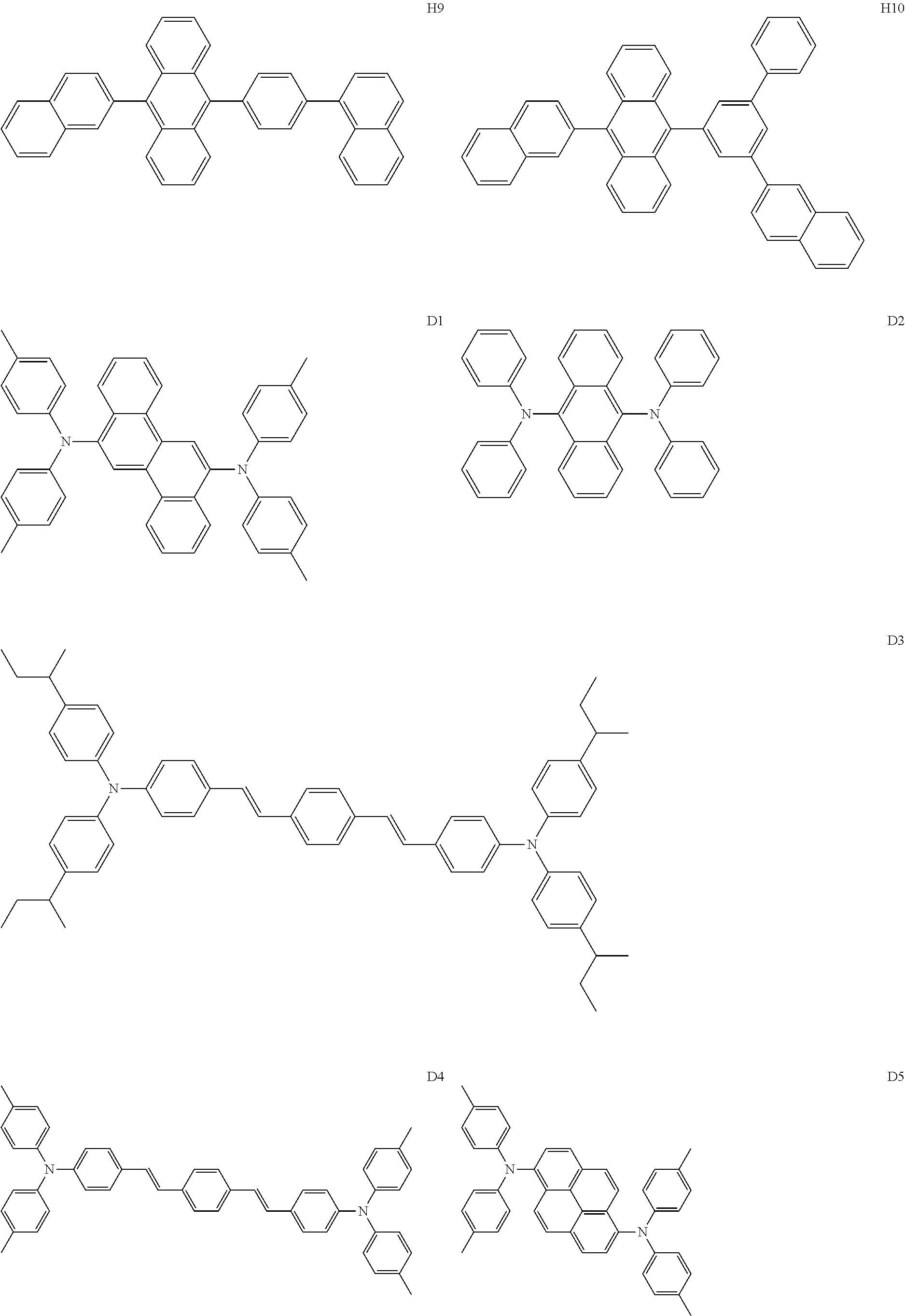

### Example 1

### (1) Preparation of an Organic EL Material Composition

To a glass bottle, 0.2 g of the compound H9, which is an anthracene derivative, 0.02 g of the compound D1, which is a dopant and 10 g of indene were added, followed by stirring to form an organic EL material composition. The concentration of the anthracene derivative was 2 wt %, and the ratio (weight ratio) of H1 and D1 was 100:10.

As for this composition, it was visually confirmed that the solution contained no insoluble matters.

### (2) Fabrication of an Organic EL Device

A glass substrate of 25 mm by 75 mm by 1.1 mm thick with a transparent electrode (GEOMATEC CO., LTD.) was subjected to ultrasonic cleaning with isopropyl alcohol for 5 minutes, and cleaned with ultraviolet rays and ozone for 30 minutes.

On the substrate, by the spin coating method, polyethylenedioxythiophene/polystyrene sulfonic acid (PEDOT:PSS) to be used in a hole-injecting layer was formed into a film with a thickness of 100 nm.

Subsequently, a toluene solution (0.6 wt %) of the following polymer 1 (Mw: 145000) was formed into a 20 nm-thick film by the spin coating method, followed by drying at 170° C. for 30 minutes. This polymer 1 film functions as a hole-transporting layer.

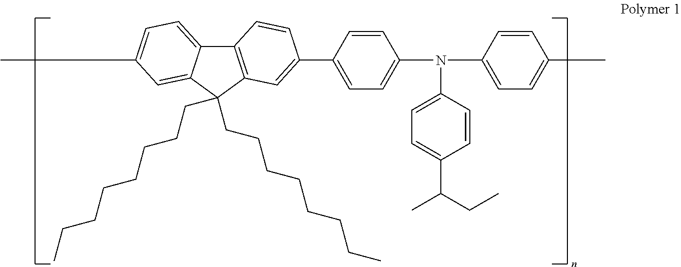

Subsequently, the composition solution prepared in (1) above was formed into a film by the spin coating method. The film thus formed was dried at 180° C. for 30 minutes in a nitrogen stream, whereby an emitting layer was formed. The film thickness of the emitting layer was 50 nm.

On the emitting layer, a 10 nm-thick tris(8-quinolinol)aluminum film (hereinafter abbreviated as the “Alq film”) was formed. This Alq film functions as an electron-transporting layer.

Then, Li as a reductive dopant (Li source: manufactured by SAES Getters Co., Ltd.) and Alq were co-deposited, whereby an Alq:Li film was formed as an electron-injecting layer (cathode). Metal aluminum was deposited on the Alq:Li film to form a metallic cathode, whereby an organic EL device was fabricated.

This organic EL device emitted blue light, and had a uniform emission surface. The luminous efficiency was 5.2 cd/A and the half life time at an initial luminance of 1,000 cd/m² was 1,500 hours.

### (3) Storage Stability of an Organic EL Material Composition

The composition prepared in (1) above was allowed to stand in a sealed state at room temperature for two weeks after the preparation. By using the composition which had been allowed to stand, an organic EL device was fabricated in the same manner as in (2) above.

The composition, characteristics and film-forming properties of the organic EL material composition are shown in Table 1.

The “characteristics of the composition” in the table shows the results of observing visibly whether there are insoluble matters in the composition after the lapse of two weeks after the preparation of the composition. Compositions which were transparent having no insoluble matters were evaluated as good, and compositions containing insoluble matters were evaluated as poor.

As for the “film-forming properties”, after drying, films which did not suffer from cissing, unevenness, generation of precipites or the like were evaluated as ◯, films which suffered from unevenness were evaluated as Δ, and films which suffered two or more selected from cissing, unevenness, generation of precipitates or the like was evaluated as ×.

TABLE 1

| | | | | Characteristics of | Film-forming |
|---|---|---|---|---|---|
| | Host | Dopant | Solvent | composition* | properties |
| Example 1 | Compound H1 | Compound D1 | Indene | Good (Transparent) | ◯ |
| Example 2 | Compound H1 | Compound D1 | Indane | Good (Transparent) | ◯ |
| Example 3 | Compound H1 | Compound D1 | 2-methylanisole | Good (Transparent) | ◯ |
| Example 4 | Compound H1 | Compound D1 | Mixed solvent* | Good (Transparent) | ◯ |
| Example 5 | Compound H2 | Compound D1 | Indene | Good (Transparent) | ◯ |
| Example 6 | Compound H3 | Compound D1 | Indene | Good (Transparent) | ◯ |
| Example 7 | Compound H4 | Compound D1 | Indene | Good (Transparent) | ◯ |
| Example 8 | Compound H5 | Compound D1 | Indene | Good (Transparent) | ◯ |
| Example 9 | Compound H6 | Compound D1 | Indene | Good (Transparent) | ◯ |
| Example 10 | Compound H7 | Compound D1 | Indene | Good (Transparent) | ◯ |
| Example 11 | Compound H8 | Compound D1 | Indene | Good (Transparent) | ◯ |
| Example 12 | Compound H9 | Compound D1 | Indene | Good (Transparent) | ◯ |
| Example 13 | Compound H10 | Compound D1 | Indene | Good (Transparent) | ◯ |
| Example 14 | Compound H2 | Compound D2 | Indene | Good (Transparent) | ◯ |
| Example 15 | Compound H2 | Compound D3 | Indene | Good (Transparent) | ◯ |
| Example 16 | Compound H2 | Compound D4 | Indene | Good (Transparent) | ◯ |
| Example 17 | Compound H2 | Compound D5 | Indene | Good (Transparent) | ◯ |
| Example 18 | Compound H3 | Compound D2 | Indene | Good (Transparent) | ◯ |
| Example 19 | Compound H3 | Compound D3 | Indene | Good (Transparent) | ◯ |
| Com. Ex. 1 | Compound H1 | Compound D1 | NMP | Good (Transparent) | Δ |
| Com. Ex. 2 | Compound H1 | Compound D1 | Toluene | Poor (Precipitated) | X |
| Com. Ex. 3 | Compound H10 | Compound D4 | Toluene | Poor (Precipitated) | X |

*The characteristics of the composition are the state after the lapse of two weeks after the preparation.
*The mixed solvent in Example 4: indene:cyclohexanone = 80:20 (wt)

TABLE 2

| | | | | Characteristics of | Film-forming |
|---|---|---|---|---|---|
| | Host | Dopant | Solvent | composition* | properties |
| Example 20 | Compound H3 | Compound D4 | Indene | Good (Transparent) | ◯ |
| Example 21 | Compound H4 | Compound D2 | Indene | Good (Transparent) | ◯ |
| Example 22 | Compound H4 | Compound D3 | Indene | Good (Transparent) | ◯ |
| Example 23 | Compound H4 | Compound D4 | Indene | Good (Transparent) | ◯ |
| Example 24 | Compound H5 | Compound D2 | Indene | Good (Transparent) | ◯ |
| Example 25 | Compound H5 | Compound D3 | Indene | Good (Transparent) | ◯ |
| Example 26 | Compound H5 | Compound D4 | Indene | Good (Transparent) | ◯ |
| Example 27 | Compound H6 | Compound D2 | Indene | Good (Transparent) | ◯ |
| Example 28 | Compound H6 | Compound D3 | Indene | Good (Transparent) | ◯ |
| Example 29 | Compound H6 | Compound D4 | Indene | Good (Transparent) | ◯ |
| Example 30 | Compound H7 | Compound D2 | Indene | Good (Transparent) | ◯ |
| Example 31 | Compound H7 | Compound D3 | Indene | Good (Transparent) | ◯ |
| Example 32 | Compound H7 | Compound D4 | Indene | Good (Transparent) | ◯ |
| Example 33 | Compound H8 | Compound D2 | Indene | Good (Transparent) | ◯ |
| Example 34 | Compound H8 | Compound D3 | Indene | Good (Transparent) | ◯ |
| Example 35 | Compound H8 | Compound D4 | Indene | Good (Transparent) | ◯ |
| Example 36 | Compound H9 | Compound D2 | Indene | Good (Transparent) | ◯ |
| Example 37 | Compound H9 | Compound D3 | Indene | Good (Transparent) | ◯ |
| Example 38 | Compound H9 | Compound D4 | Indene | Good (Transparent) | ◯ |
| Example 39 | Compound H10 | Compound D2 | Indene | Good (Transparent) | ◯ |
| Example 40 | Compound H10 | Compound D3 | Indene | Good (Transparent) | ◯ |
| Example 41 | Compound H10 | Compound D4 | Indene | Good (Transparent) | ◯ |

TABLE 3

| | | | | Characteristics of | Film-forming |
|---|---|---|---|---|---|
| | Host | Dopant | Solvent | composition* | properties |
| Example 42 | Compound H2 | Compound D1 | Indane | Good (Transparent) | ◯ |
| Example 43 | Compound H2 | Compound D2 | Indane | Good (Transparent) | ◯ |
| Example 44 | Compound H2 | Compound D3 | Indane | Good (Transparent) | ◯ |
| Example 45 | Compound H2 | Compound D4 | Indane | Good (Transparent) | ◯ |
| Example 46 | Compound H3 | Compound D1 | Indane | Good (Transparent) | ◯ |
| Example 47 | Compound H3 | Compound D2 | Indane | Good (Transparent) | ◯ |
| Example 48 | Compound H3 | Compound D3 | Indane | Good (Transparent) | ◯ |
| Example 49 | Compound H3 | Compound D4 | Indane | Good (Transparent) | ◯ |
| Example 50 | Compound H4 | Compound D1 | Indane | Good (Transparent) | ◯ |
| Example 51 | Compound H4 | Compound D2 | Indane | Good (Transparent) | ◯ |
| Example 52 | Compound H4 | Compound D3 | Indane | Good (Transparent) | ◯ |
| Example 53 | Compound H4 | Compound D4 | Indane | Good (Transparent) | ◯ |
| Example 54 | Compound H5 | Compound D1 | Indane | Good (Transparent) | ◯ |
| Example 55 | Compound H5 | Compound D2 | Indane | Good (Transparent) | ◯ |
| Example 56 | Compound H5 | Compound D3 | Indane | Good (Transparent) | ◯ |
| Example 57 | Compound H5 | Compound D4 | Indane | Good (Transparent) | ◯ |
| Example 58 | Compound H6 | Compound D1 | Indane | Good (Transparent) | ◯ |
| Example 59 | Compound H6 | Compound D2 | Indane | Good (Transparent) | ◯ |
| Example 60 | Compound H6 | Compound D3 | Indane | Good (Transparent) | ◯ |
| Example 61 | Compound H6 | Compound D4 | Indane | Good (Transparent) | ◯ |
| Example 62 | Compound H7 | Compound D1 | Indane | Good (Transparent) | ◯ |
| Example 63 | Compound H7 | Compound D2 | Indane | Good (Transparent) | ◯ |
| Example 64 | Compound H7 | Compound D3 | Indane | Good (Transparent) | ◯ |
| Example 65 | Compound H7 | Compound D4 | Indane | Good (Transparent) | ◯ |

TABLE 4

| | | | | Characteristics of | Film-forming |
|---|---|---|---|---|---|
| | Host | Dopant | Solvent | composition* | properties |
| Example 66 | Compound H8 | Compound D1 | Indane | Good (Transparent) | ◯ |
| Example 67 | Compound H8 | Compound D2 | Indane | Good (Transparent) | ◯ |
| Example 68 | Compound H8 | Compound D3 | Indane | Good (Transparent) | ◯ |
| Example 69 | Compound H8 | Compound D4 | Indane | Good (Transparent) | ◯ |
| Example 70 | Compound H9 | Compound D1 | Indane | Good (Transparent) | ◯ |
| Example 71 | Compound H9 | Compound D2 | Indane | Good (Transparent) | ◯ |
| Example 72 | Compound H9 | Compound D3 | Indane | Good (Transparent) | ◯ |
| Example 73 | Compound H9 | Compound D4 | Indane | Good (Transparent) | ◯ |
| Example 74 | Compound H10 | Compound D1 | Indane | Good (Transparent) | ◯ |
| Example 75 | Compound H10 | Compound D2 | Indane | Good (Transparent) | ◯ |
| Example 76 | Compound H10 | Compound D3 | Indane | Good (Transparent) | ◯ |
| Example 77 | Compound H10 | Compound D4 | Indane | Good (Transparent) | ◯ |
| Example 78 | Compound H1 | Compound D5 | Indene | Good (Transparent) | ◯ |
| Example 79 | Compound H2 | Compound D5 | Indene | Good (Transparent) | ◯ |
| Example 80 | Compound H3 | Compound D5 | Indene | Good (Transparent) | ◯ |
| Example 81 | Compound H4 | Compound D5 | Indene | Good (Transparent) | ◯ |
| Example 82 | Compound H5 | Compound D5 | Indene | Good (Transparent) | ◯ |
| Example 83 | Compound H6 | Compound D5 | Indene | Good (Transparent) | ◯ |
| Example 84 | Compound H7 | Compound D5 | Indene | Good (Transparent) | ◯ |
| Example 85 | Compound H8 | Compound D5 | Indene | Good (Transparent) | ◯ |
| Example 86 | Compound H9 | Compound D5 | Indene | Good (Transparent) | ◯ |
| Example 87 | Compound H10 | Compound D5 | Indene | Good (Transparent) | ◯ |

### Examples 2 to 87

The organic EL material composition and the organic EL device were prepared and evaluated in the same manner as in Example 1, except that the anthracene derivative (host), the dopant and the solvent shown in Table 1 were used.

The results are shown in Tables 1 to 4.

### Comparative Example 1

An organic EL material composition and an organic EL device were fabricated and evaluated in the same manner as in Example 1, except that 1-methyl-2-pyrrolidinone was used as the solvent.

The device emitted blue light, and had a uniform emission surface. The luminous efficiency was lowered to 4.1 cd/A. The results are shown in Table 1.

### Comparative Examples 2 and 3

Organic EL material compositions and organic EL devices were prepared and evaluated in the same manner as in Example 1, except that the anthracene derivative (host), the dopant and the solvent shown in Table 1 were used. The results are shown in Table 1.

### INDUSTRIAL APPLICABILITY

The organic EL material composition of the invention can be preferably used as a coating liquid used for forming an organic thin film layer, in particular, for forming an emitting layer.

The organic EL device of the invention can be suitably used as various displays, a light source such as a planar emitting material and backlight of a display, a display part of a portable phone, a PDA, a car navigation system, or an instrument panel of an automobile, an illuminator, and the like.

The contents of the above-mentioned documents are herein incorporated by reference in its entirety.

1. An organic electroluminescence material composition comprising a solvent represented by the following formula (1) and an anthracene derivative: 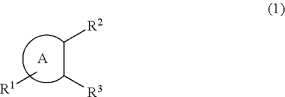
wherein ring A is an aliphatic ring or an aromatic ring having 4 to 8 carbon atoms;
R¹ is a substituent on the ring A, which may be present in plural on the ring A, and is independently a hydrogen atom, a substituted or unsubstituted alkyl group having 1 to 10 carbon atoms, a substituted or unsubstituted cycloalkyl group, a substituted or unsubstituted alkoxy group having 1 to 10 carbon atoms, a substituted or unsubstituted aryl group having 6 to 10 ring carbon atoms, a substituted or unsubstituted aralkyl group having 7 to 11 carbon atoms, a substituted or unsubstituted aryloxy group having 6 to 10 ring atoms, a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group, or a nitro group;
R² and R³ are substituents connected to adjacent carbon atoms on the ring A, which are independently a substituted or unsubstituted alkyl group having 1 to 10 carbon atoms, a substituted or unsubstituted alkenyl group having 1 to 10 carbon atoms, a substituted or unsubstituted cycloalkyl group, a substituted or unsubstituted cycloalkenyl group, a substituted or unsubstituted alkoxy group having 1 to 10 carbon atoms, a substituted or unsubstituted aryl group having 6 to 10 ring carbon atoms, a substituted or unsubstituted aralkyl group having 7 to 11 carbon atoms, a substituted or unsubstituted aryloxy group having 6 to 10 ring atoms, a substituted or unsubstituted arylthio group having 6 to 10 ring atoms, a substituted or unsubstituted alkoxycarbonyl group having 1 to 10 carbon atoms, a substituted or unsubstituted silyl group, a carboxy group, a halogen atom, a cyano group or a nitro group; and R² and R³ may be combined with each other to form a ring.

2. The organic electroluminescence material composition according to claim 1, wherein the ring A is a hydrocarbon ring having 6 carbon atoms.

3. The organic electroluminescence material composition according to claim 1, wherein the R² and R³ are combined with each other to form a ring, and the ring is a substituted or unsubstituted hydrocarbon ring having 4 to 10 carbon atoms or a substituted or unsubstituted heterocyclic ring having 2 to 10 carbon atoms.

4. The organic electroluminescence material composition according to claim 1, wherein the ring formed by R² and R³ are substituted or unsubstituted cyclopentane, substituted or unsubstituted cyclopentene, substituted or unsubstituted cyclopentadiene, substituted or unsubstituted benzene, substituted or unsubstituted cyclohexadiene, substituted or unsubstituted cyclohexane, substituted or unsubstituted cycloheptatriene, substituted or unsubstituted cycloheptadiene, substituted or unsubstituted cycloheptene or substituted or unsubstituted cycloheptane.

5. The organic electroluminescence material composition according to claim 1, wherein R¹ to R³ are independently a substituted or unsubstituted alkyl group having 1 to 10 carbon atoms.

6. The organic electroluminescence material composition according to claim 1, wherein the anthracene derivative has a molecular weight of 4000 or less.

7. The organic electroluminescence material composition according to claim 6, wherein the anthracene derivative is a compound represented by the following formula (3): 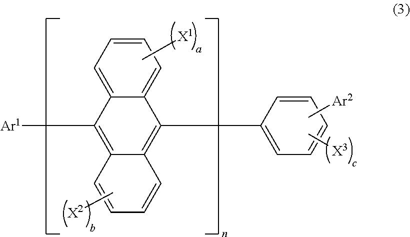
wherein Ar¹ is a substituted or unsubstituted fused aromatic group having 10 to 50 ring carbon atoms;
Ar² is a substituted or unsubstituted aromatic group having 6 to 50 ring carbon atoms;
X¹ to X³ are independently a substituted or unsubstituted aromatic group having 6 to 50 ring carbon atoms, a substituted or unsubstituted aromatic heterocyclic group having 5 to 50 ring atoms, a substituted or unsubstituted alkyl group having 1 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a carboxy group, a halogen atom, a cyano group, a nitro group, or a hydroxyl group;
a, b and c are independently an integer of 0 to 4; and
n is an integer of 1 to 3, and when n is 2 or more, the groups in [ ] may be the same or different.

8. The electroluminescence material composition according to claim 1, which further comprises one or more dopants.

9. The electroluminescence material composition according to claim 8, wherein the dopant is a styrylamine derivative represented by the following formula (8): 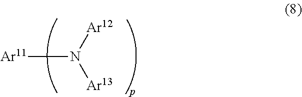
wherein Ar¹¹ is a residue corresponding to benzene, biphenyl, terphenyl, stilbene or distyrylarene; Ar¹² and Ar¹³, which each may be substituted, are independently a hydrogen atom or an aromatic group having 6 to 20 carbon atoms; p is an integer of 1 to 4; and at least one of Ar¹¹ to Ar¹³ is a styryl group or a group having a styryl group.

10. The organic electroluminescence material composition according to claim 8, wherein the dopant is an arylamine derivative represented by the formula (9): 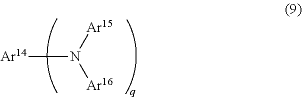
wherein Ar¹⁴ is a residue corresponding to a substituted or unsubstituted arene having 5 to 40 ring carbon atoms; Ar¹⁵ and Ar¹⁶ are independently a substituted or unsubstituted aryl group having 5 to 40 ring carbon atoms; and q is an integer of 1 to 4.

11. A method for forming a thin film comprising applying the organic electroluminescence material composition according to claim 1 on a base to form a film, and removing a solvent from the film.

12. An organic electroluminescence device comprising:
an anode and a cathode; and
one or more organic thin film layers comprising an emitting layer between the anode and the cathode;
at least one of the organic thin film layers being a thin film obtained by the method according to claim 11.
